(19) United States
(12) Patent Application Publication
(10) Pub. No.: US 2010/0192037 A1
(43) Pub. Date: Jul. 29, 2010

(54) RADIO COMMUNICATION APPARATUS AND REDUNDANCY VERSION TRANSMISSION CONTROL METHOD

(75) Inventors: Kenichi Kuri, Osaka (JP); Akihiko Nishio, Osaka (JP); Hao Jiang, Beijing (CN); Katsuhiko Hiramatsu, Osaka (JP)

Correspondence Address: Dickinson Wright PLLC;James E. Ledbetter, Esq., International Square, 1875 Eye Street, N.W., Suite 1200, Washington, DC, 20006, US

(73) Assignee: PANASONIC CORPORATION, Osaka (JP)

(21) Appl. No.: 12/595,427

(22) PCT Filed: Apr. 13, 2007
(86) PCT No.: PCT/CN2007/001211

§ 371 Date: Mar. 25, 2010

(51) Int. Cl. H03M 13/05; G06F 11/10

(52) U.S. Cl. 714/752; 714/E11.032

(57) ABSTRACT

Optimal error rate performance can always be obtained and the number of retransmissions can be minimized in IR-type HARQ using an LDPC code as an error correction code. An LDPC encoding section 101 performs LDPC encoding on a transmission bit sequence-using parity check matrix, generates an LDPC codeword comprising systematic bits and parity bits and outputs this to an RV control section 102, and also outputs the parity check matrix to RV control section 102, and RV control section 102 controls the transmission order of a plurality of redundancy versions according to the size of the parity check matrix column degree of each bit belonging to each of the plurality of redundancy versions.

### TECHNICAL FIELD

The present invention relates to a radio communication apparatus and redundancy version transmission control method.

### BACKGROUND ART

In recent years, multimedia communication such as data communication and video streaming has continued to increase in popularity. Therefore, data sizes are expected to increase even more in the future, and growing demands for higher data rates for mobile communication services are also anticipated.

Thus, a fourth-generation mobile communication system called IMT-Advanced has been studied by the ITU-R (International Telecommunication Union Radio Communication Sector), and an LDPC (Low-Density Parity-Check) code is one of error correction codes for implementing a downlink speed of up to 1 Gbps. Use of an LDPC code as an error correction code enables decoding processing to be parallelized, allowing decoding processing to be speeded up compared with the use of a turbo code that requires repeated serial execution of decoding processing.

LDPC encoding is performed using a parity check matrix containing a large number of 0s and a small number of 1s. A transmitting-side radio communication apparatus encodes a transmission bit sequence using a parity check matrix, and obtains an LDPC codeword comprising systematic bits and parity bits. A receiving-side radio communication apparatus decodes received data by iteratively executing passing of the likelihood of individual bits in the parity check matrix row direction and the parity check matrix column direction, and obtains a received bit sequence. Here, the number of 1s contained in each column in a parity check matrix is called the column degree, and the number of 1s contained in each row in a parity check matrix is called the row degree. A parity check matrix can be represented by a Tanner graph, which is a two-part graph comprising rows and columns. In a Tanner graph, each row of a parity check matrix is called a check node, and each column of a parity check matrix is called a variable node. Variable nodes and check nodes of a Tanner graph are connected in accordance with the arrangement of 1s in the parity check matrix, and a receiving-side radio communication apparatus decodes receive data by iteratively executing passing of likelihoods between connected nodes, and obtains a received bit sequence.

HARQ (Hybrid ARQ) combines ARQ (Automatic Repeat reQuest) and error correction coding. With HARQ, a receiving-side radio communication apparatus feeds back an ACK (Acknowledgment) signal as a response signal to the transmitting-side radio communication apparatus if there are no errors in receive data, and feeds back a NACK (Negative Acknowledgment) signal if there is an error. Also, the receiving-side radio communication apparatus combines retransmitted data from the transmitting-side radio communication apparatus with received data in the past, and decodes the combined data. By this means SINR and coding gain improvements are achieved, and received data can be decoded with fewer retransmissions than in the case of ordinary ARQ.

IR (Incremental Redundancy) is one of HARQ methods. With the IR method, a codeword is divided into a plurality of redundancy versions (hereinafter referred to as “RVs”), which are retransmission data units, and these RVs are transmitted sequentially.

One conventional IR-type HARQ method composes each RV by extracting coded bits randomly from a codeword (refer to Non-patent Document 1).

Non-patent Document 1: 3GPP-TS.25.212 Sec.4.2.7.5 “Rate matching pattern determination”, 2002/03

### DISCLOSURE OF INVENTION

### Problems to be Solved by the Invention

Here, in LDPC encoding, error rate performance varies between variable nodes according to the number of check node connections of each variable node. Therefore, when IR-type HARQ is performed using an LDPC code as an error correction code, since an RV is composed by simply extracting coded bits randomly from a codeword disregarding the number of connections, it may not be possible for optimal error rate performance to be obtained, resulting in an increase in the number of retransmissions.

It is an object of the present invention to provide a radio communication apparatus and RV transmission control method that enable optimal error rate performance always to be obtained and the number of retransmissions to be minimized in IR-type HARQ using an LDPC code as an error correction code.

### Means for Solving the Problems

A radio communication apparatus of the present invention is a transmitting-side radio communication apparatus that extracts each bit of a codeword comprising a systematic bit and a parity bit obtained by LDPC encoding based on a parity check matrix to compose a plurality of RVs, and transmits the plurality of RVs sequentially, and employs a configuration that includes an encoding section that encodes a transmission bit sequence by the LDPC encoding based on the parity check matrix to generate the codeword, and a control section that controls a transmission order of the plurality of RVs according to a column degree of each bit belonging to the plurality of RVs, in the parity check matrix.

### ADVANTAGEOUS EFFECT OF THE INVENTION

The present invention enables optimal error rate performance always to be obtained and the number of retransmissions to be minimized in IR-type HARQ using an LDPC code as an error correction code.

### BRIEF DESCRIPTION OF DRAWINGS

FIG. 1 is a block configuration diagram of a transmitting-side radio communication apparatus according to Embodiment 1 of the present invention;

FIG. 2 is a parity check matrix according to Embodiment 1 of the present invention;

FIG. 3 is a Tanner graph according to Embodiment 1 of the present invention;

FIG. 4 is a drawing showing an RV configuration according to Embodiment 1 of the present invention;

FIG. 5 is a drawing showing transmission processing according to Embodiment 1 of the present invention;

FIG. 6 is a block configuration diagram of a receiving-side radio communication apparatus according to Embodiment 1 of the present invention;

FIG. 7 is a drawing showing combining processing according to Embodiment 1 of the present invention;

FIG. 8 is a drawing showing transmission processing according to Embodiment 2 of the present invention;

FIG. 9 is a drawing showing an RV configuration according to Embodiment 3 of the present invention;

FIG. 10 is a drawing showing transmission processing according to Embodiment 3 of the present invention;

FIG. 11 is a drawing showing an RV configuration according to Embodiment 4 of the present invention;

FIG. 12 is a drawing showing transmission processing according to Embodiment 4 of the present invention;

FIG. 13 is a drawing showing an RV configuration according to Embodiment 5 of the present invention;

FIG. 14 is a drawing showing transmission processing according to Embodiment 5 of the present invention;

FIG. 15 is a parity check matrix according to Embodiment 6 of the present invention;

FIG. 16 is a Tanner graph according to Embodiment 6 of the present invention;

FIG. 17 is a drawing showing an RV configuration according to Embodiment 6 of the present invention;

FIG. 18 is a drawing showing transmission processing according to Embodiment 6 of the present invention;

FIG. 19 is a drawing showing an RV configuration according to Embodiment 7 of the present invention; and

FIG. 20 is a drawing showing transmission processing according to Embodiment 7 of the present invention.

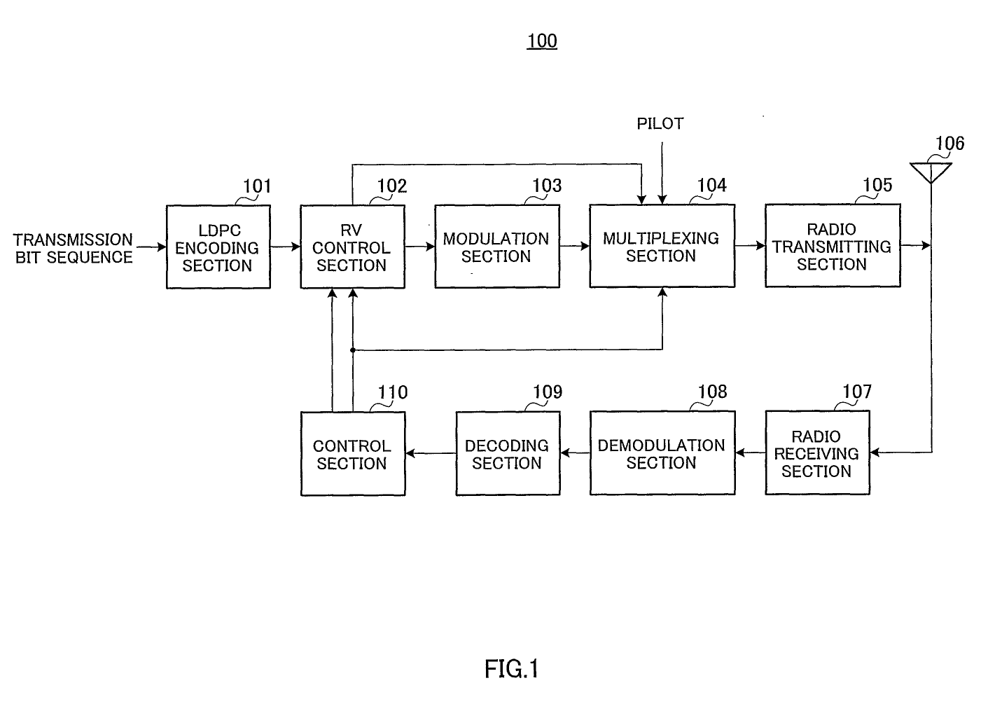

### FIG. 1

TRANSMISSION BIT SEQUENCE
101 LDPC ENCODING SECTION
102 RV CONTROL SECTION
103 MODULATION SECTION
PILOT
104 MULTIPLEXING SECTION
105 RADIO TRANSMITTING SECTION
107 RADIO RECEIVING SECTION
108 DEMODULATION SECTION
109 DECODING SECTION
110 CONTROL SECTION

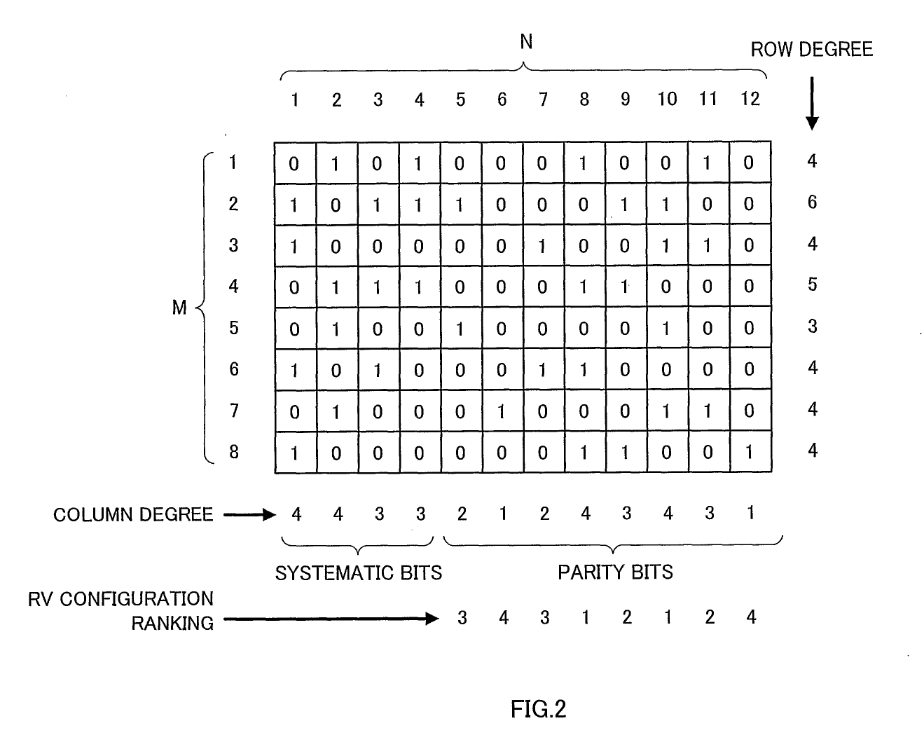

### FIG. 2

ROW DEGREE
COLUMN DEGREE
SYSTEMATIC BITS
PARITY BITS
RV CONFIGURATION RANKING

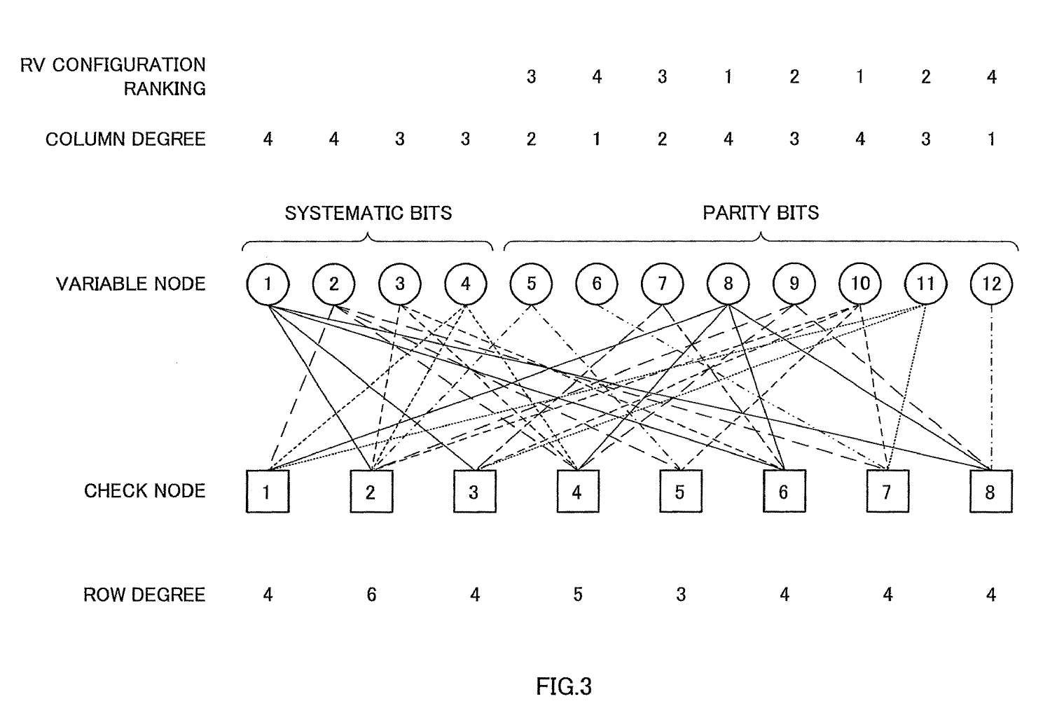

### FIG. 3

RV CONFIGURATION RANKING
COLUMN DEGREE
SYSTEMATIC BITS
PARITY BITS
VARIABLE NODE
CHECK NODE
ROW DEGREE

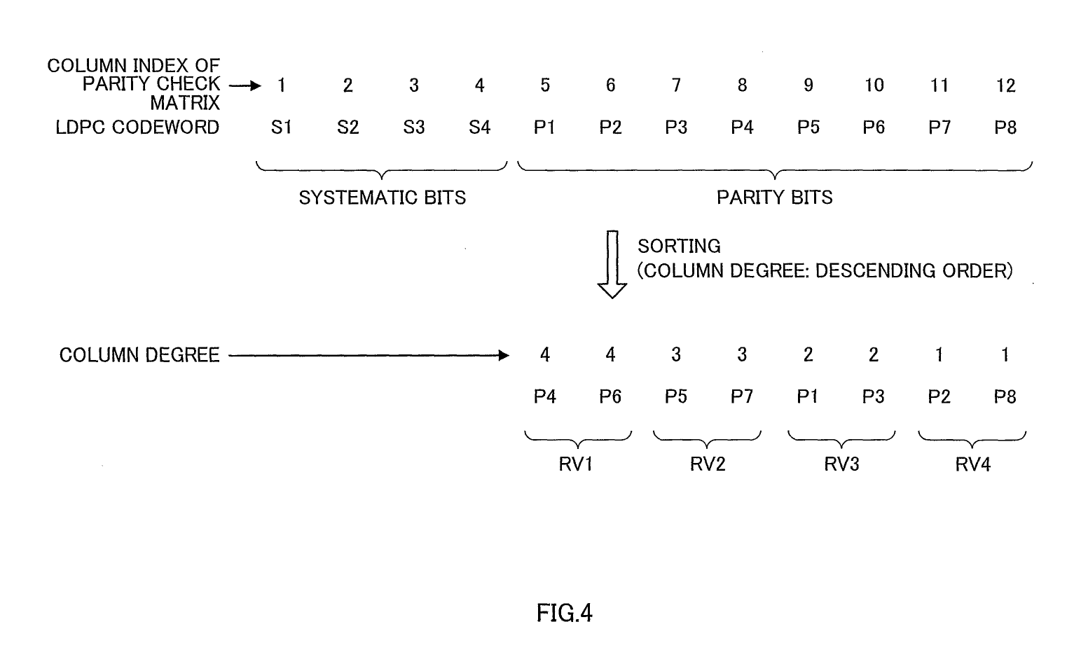

### FIG. 4

COLUMN INDEX OF PARITY CHECK MATRIX
LDPC CODEWORD
SYSTEMATIC BITS
PARITY BITS
   SORTING
   (COLUMN DEGREE: DESCENDING ORDER)
COLUMN DEGREE

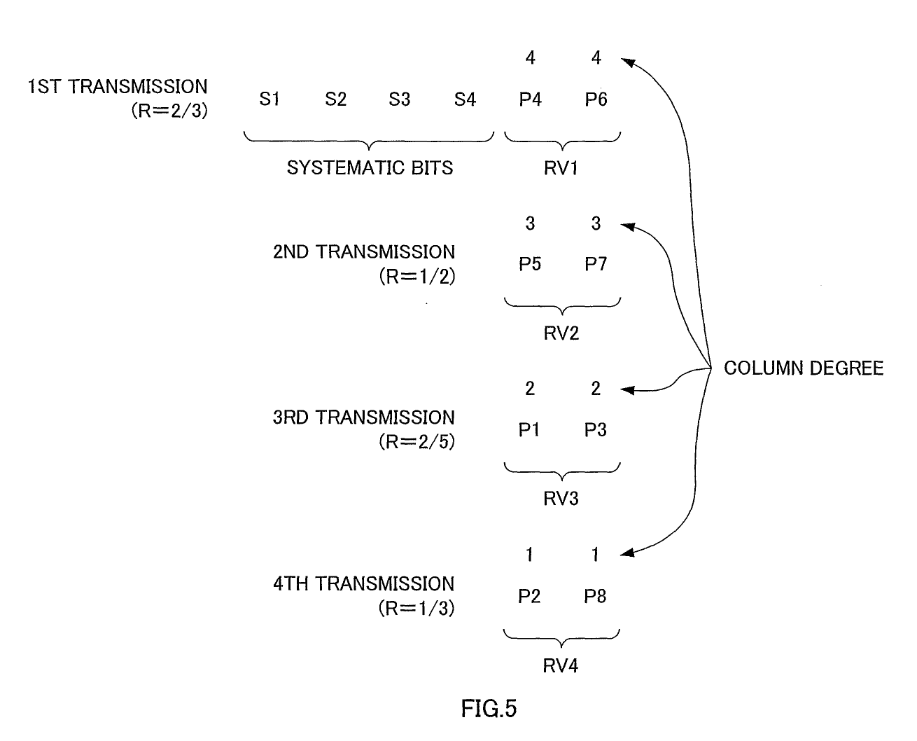

### FIG. 5

1ST TRANSMISSION
SYSTEMATIC BITS
2ND TRANSMISSION
3RD TRANSMISSION
4TH TRANSMISSION
COLUMN DEGREE

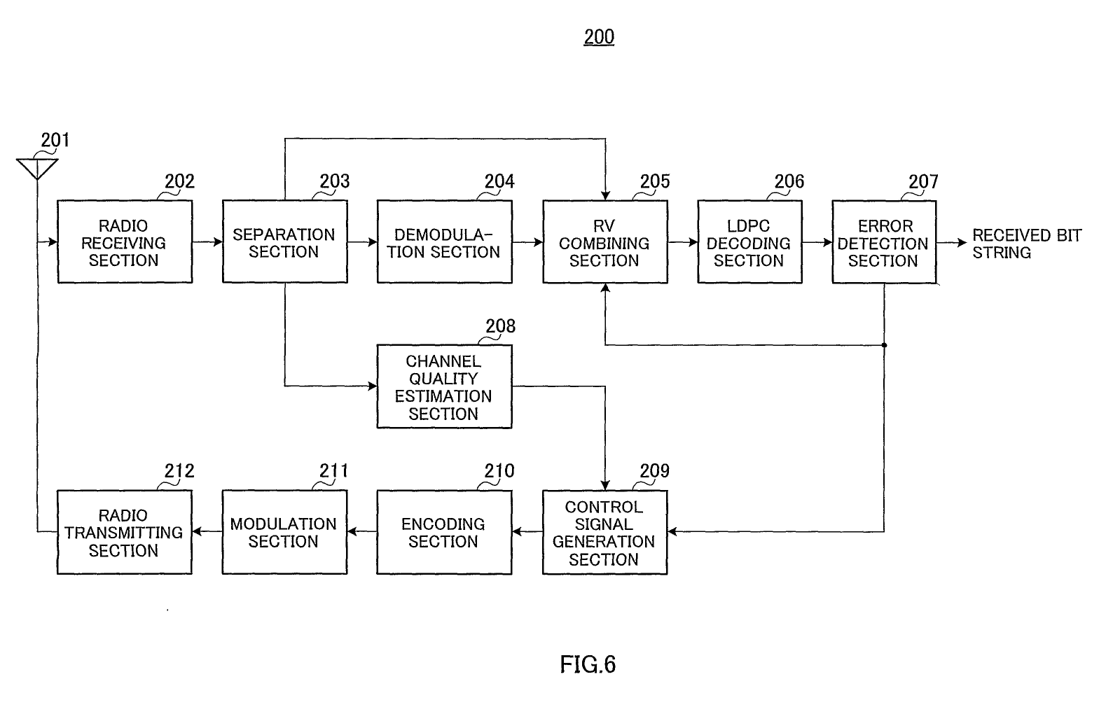

### FIG. 6

202 RADIO RECEIVING SECTION
203 SEPARATION SECTION
204 DEMODULATION SECTION
205 RV COMBINING SECTION
206 LDPC DECODING SECTION
207 ERROR DETECTION SECTION
RECEIVED BIT SEQUENCE
208 CHANNEL QUALITY ESTIMATION SECTION
209 CONTROL SIGNAL GENERATION SECTION
210 ENCODING SECTION
211 MODULATION SECTION
212 RADIO TRANSMITTING SECTION

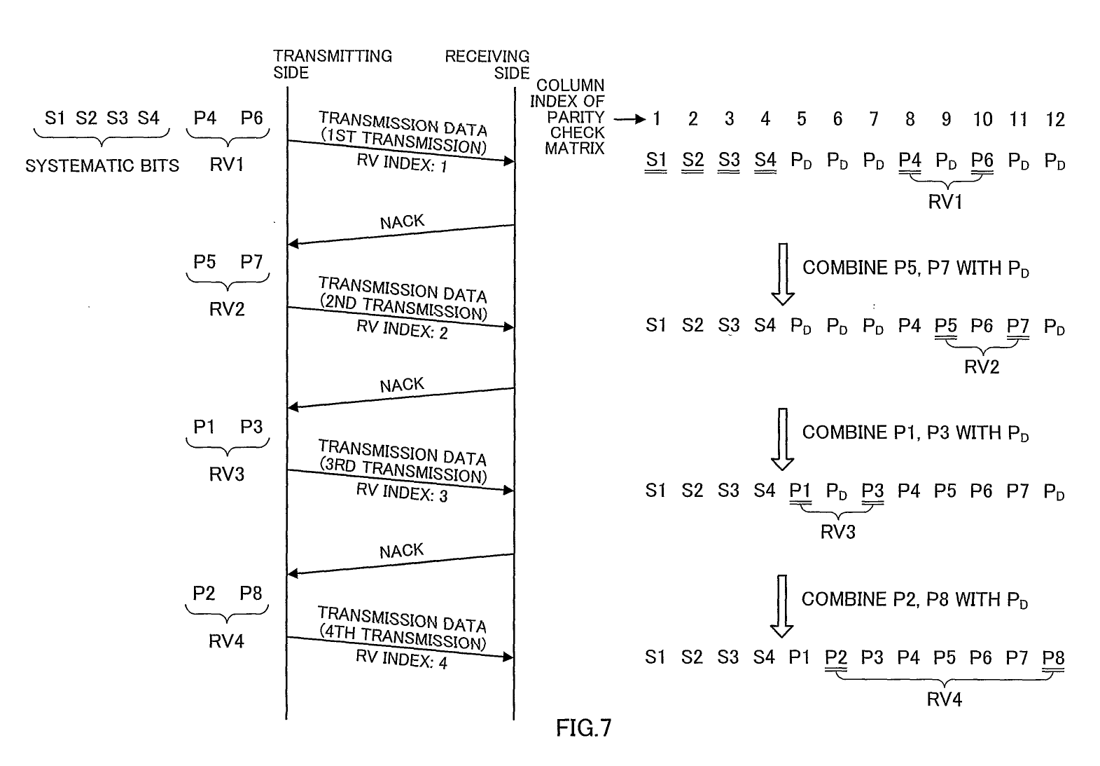

### FIG. 7

SYSTEMATIC BITS
TRANSMITTING SIDE
RECEIVING SIDE
TRANSMISSION DATA (1ST TRANSMISSION) RV INDEX: 1
TRANSMISSION DATA (2ND TRANSMISSION) RV INDEX: 2
TRANSMISSION DATA (3RD TRANSMISSION) RV INDEX: 3
TRANSMISSION DATA (4TH TRANSMISSION) RV INDEX: 4
COLUMN INDEX OF PARITY CHECK MATRIX
COMBINE P5, P7 WITH P_{D}
COMBINE P1, P3 WITH P_{D}
COMBINE P2, P8 WITH P_{D}

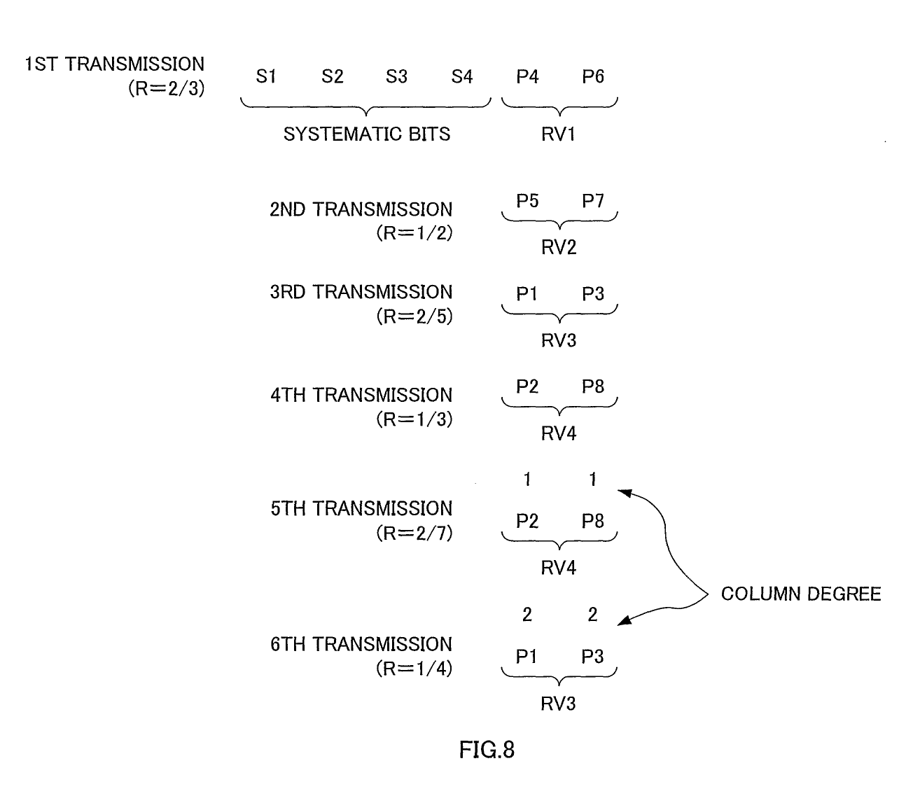

### FIG. 8

1ST TRANSMISSION
SYSTEMATIC BITS
2ND TRANSMISSION
3RD TRANSMISSION
4TH TRANSMISSION
5TH TRANSMISSION
6TH TRANSMISSION
COLUMN DEGREE

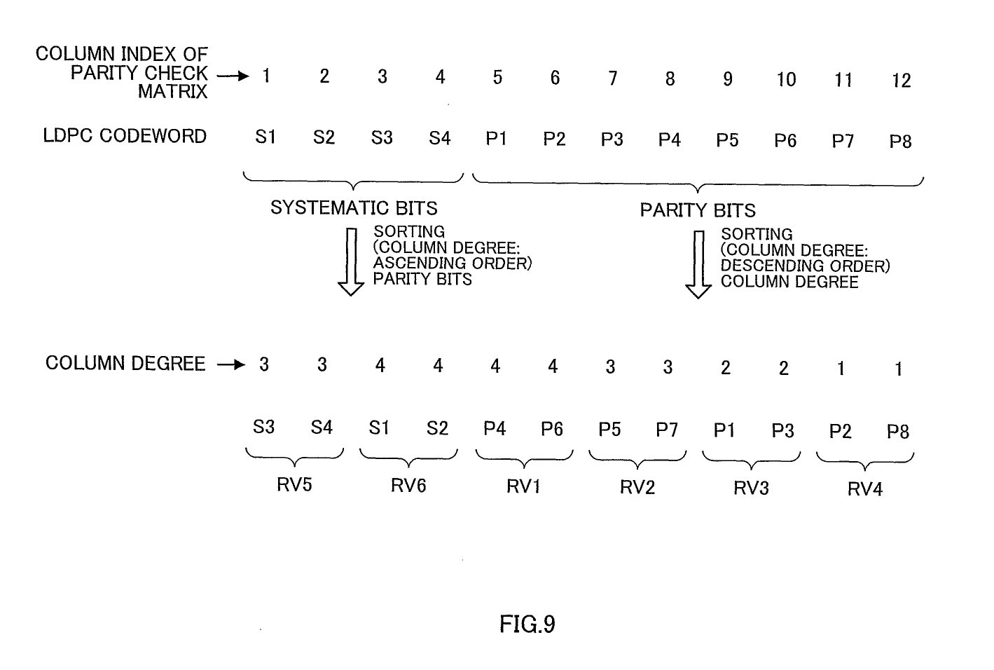

### FIG. 9

COLUMN INDEX OF PARITY CHECK MATRIX
LDPC CODEWORD
SYSTEMATIC BITS
   SORTING
   (COLUMN DEGREE: ASCENDING ORDER)
PARITY BITS
   SORTING
   (COLUMN DEGREE: DESCENDING ORDER)
COLUMN DEGREE

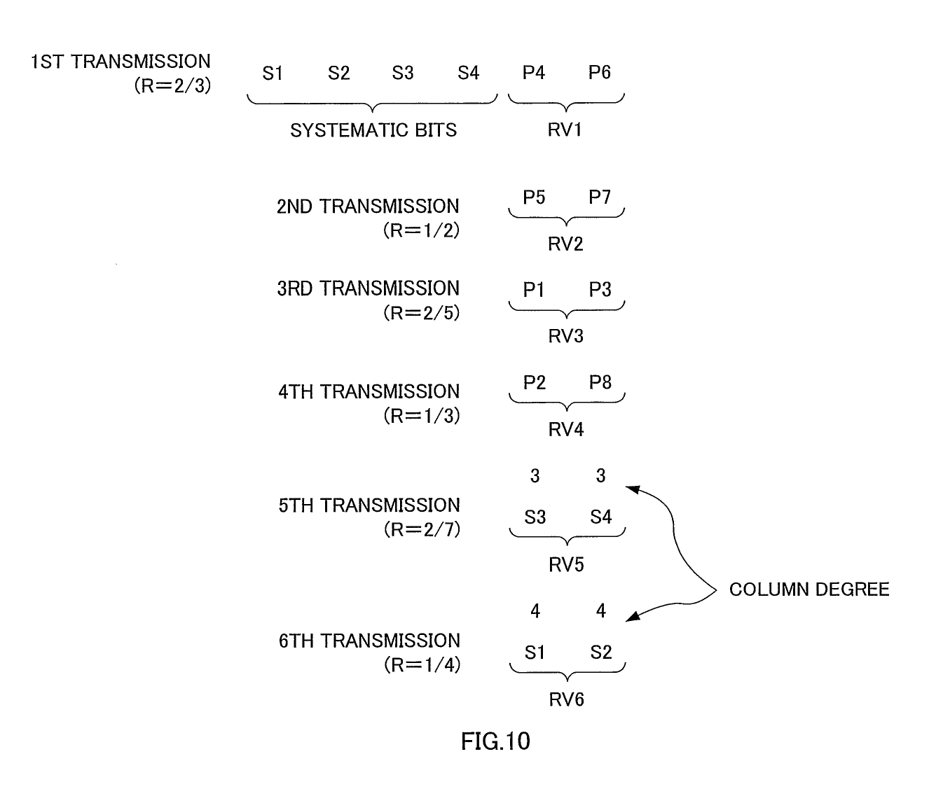

### FIG. 10

1ST TRANSMISSION
SYSTEMATIC BITS
2ND TRANSMISSION
3RD TRANSMISSION
4TH TRANSMISSION
5TH TRANSMISSION
6TH TRANSMISSION
COLUMN DEGREE

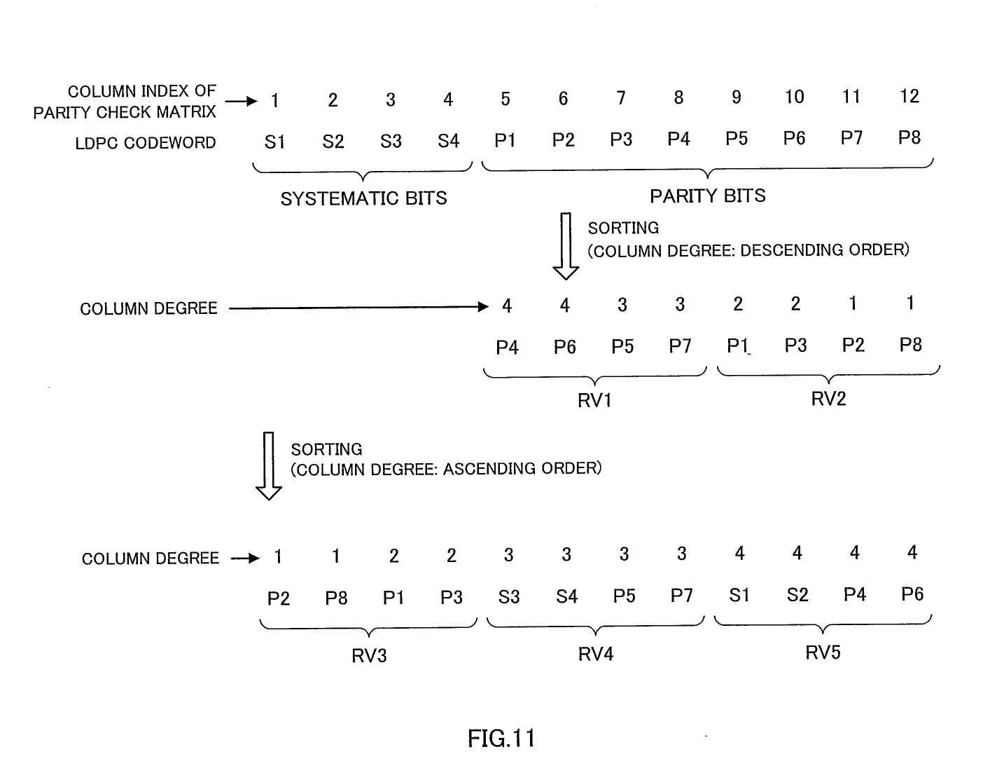

### FIG. 11

COLUMN INDEX OF PARITY CHECK MATRIX
LDPC CODEWORD
SYSTEMATIC BITS
PARITY BITS
   SORTING
   (COLUMN DEGREE: DESCENDING ORDER)
COLUMN DEGREE
   SORTING
   (COLUMN DEGREE: ASCENDING ORDER)
COLUMN DEGREE

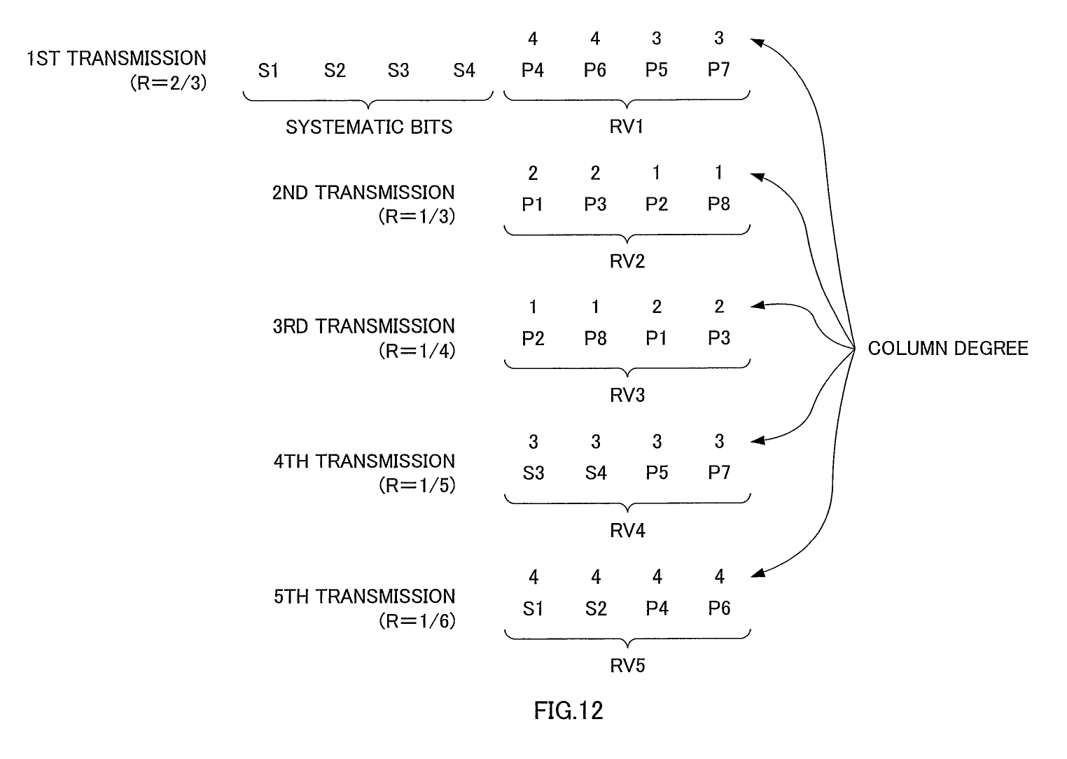

### FIG. 12

1ST TRANSMISSION
SYSTEMATIC BITS
2ND TRANSMISSION
3RD TRANSMISSION
4TH TRANSMISSION
5TH TRANSMISSION
COLUMN DEGREE

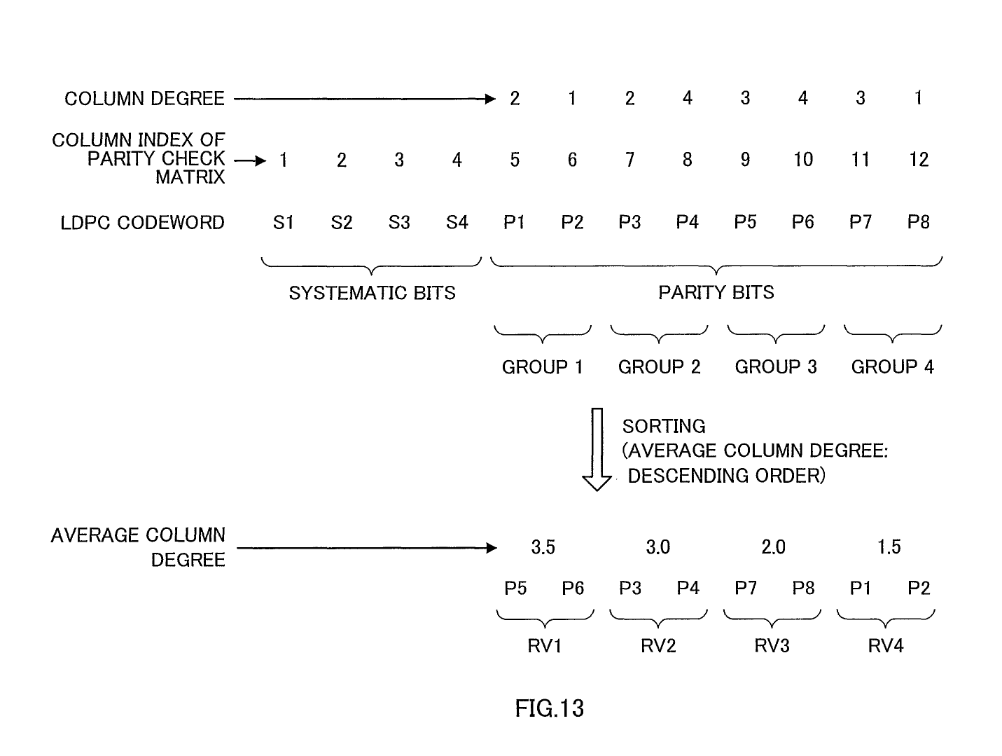

### FIG. 13

COLUMN DEGREE
COLUMN INDEX OF PARITY CHECK MATRIX
LDPC CODEWORD
SYSTEMATIC BITS
PARITY BITS
GROUP 1 GROUP 2 GROUP 3 GROUP 4
   SORTING
   (AVERAGE COLUMN DEGREE: DESCENDING ORDER)
AVERAGE COLUMN DEGREE

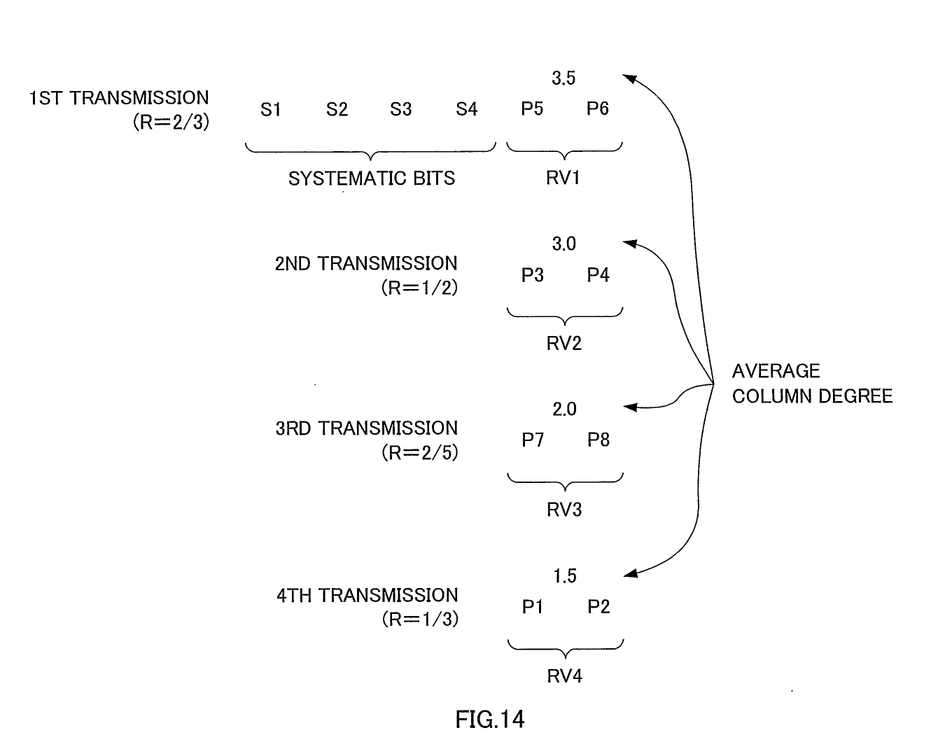

### FIG. 14

1ST TRANSMISSION
SYSTEMATIC BITS
2ND TRANSMISSION
3RD TRANSMISSION
4TH TRANSMISSION
AVERAGE COLUMN DEGREE

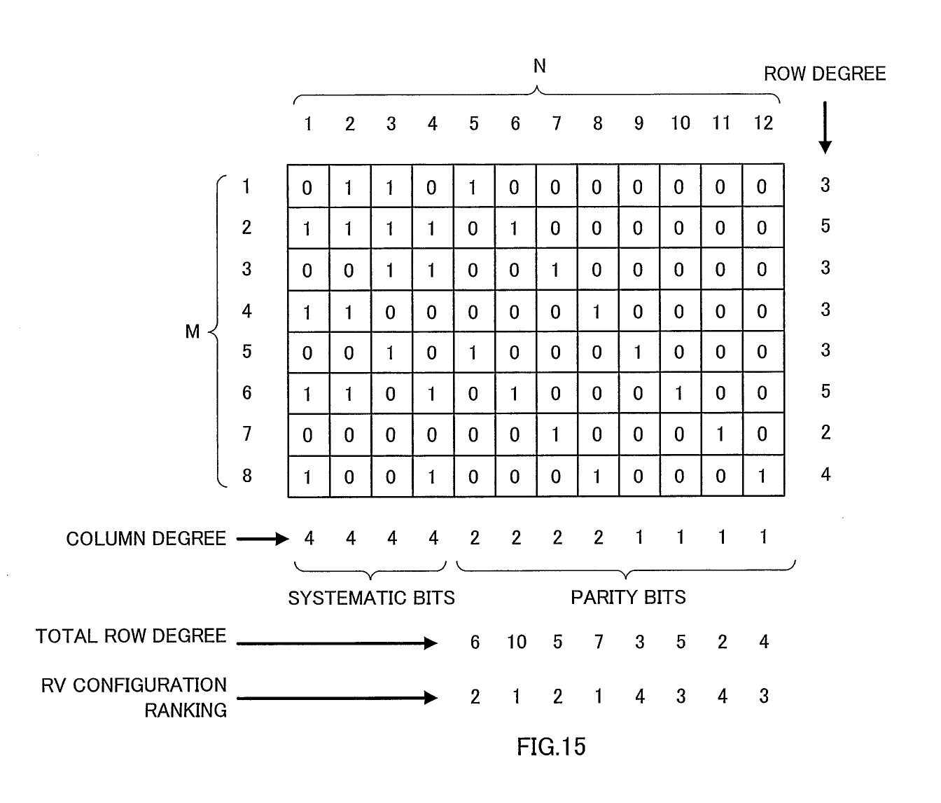

### FIG. 15

ROW DEGREE
COLUMN DEGREE
SYSTEMATIC BITS
PARITY BITS
TOTAL ROW DEGREE
RV CONFIGURATION RANKING

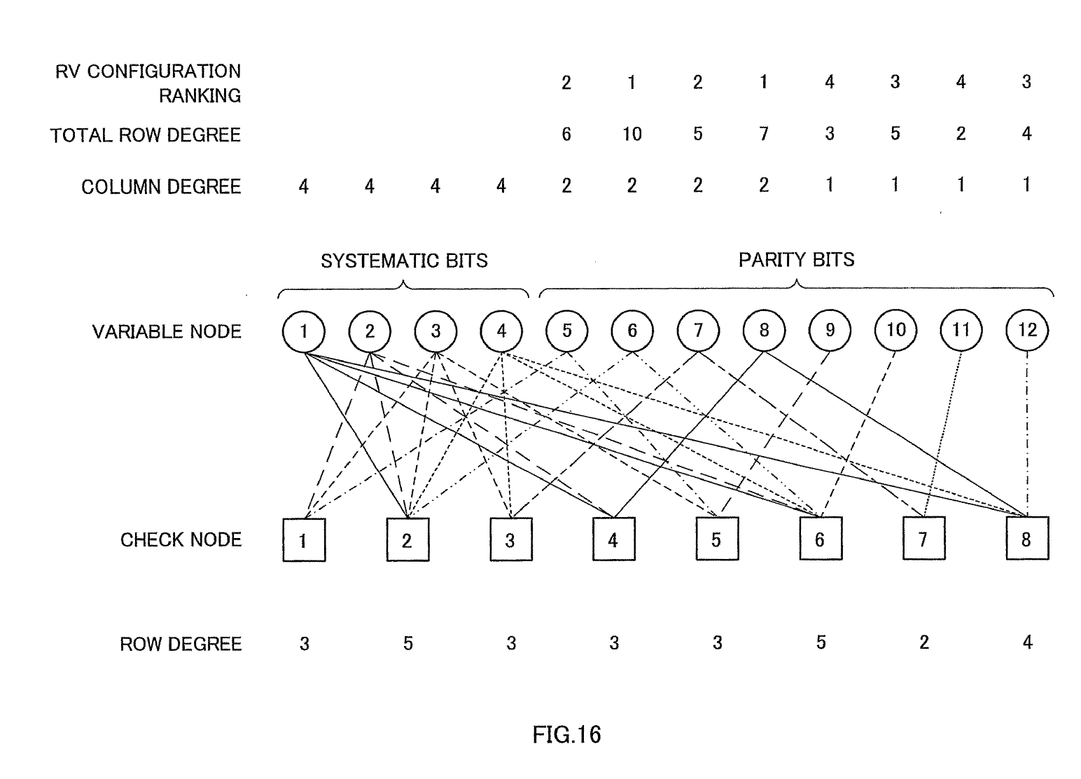

### FIG. 16

RV CONFIGURATION RANKING
TOTAL ROW DEGREE
COLUMN DEGREE
SYSTEMATIC BITS
PARITY BITS
VARIABLE NODE
CHECK NODE
ROW DEGREE

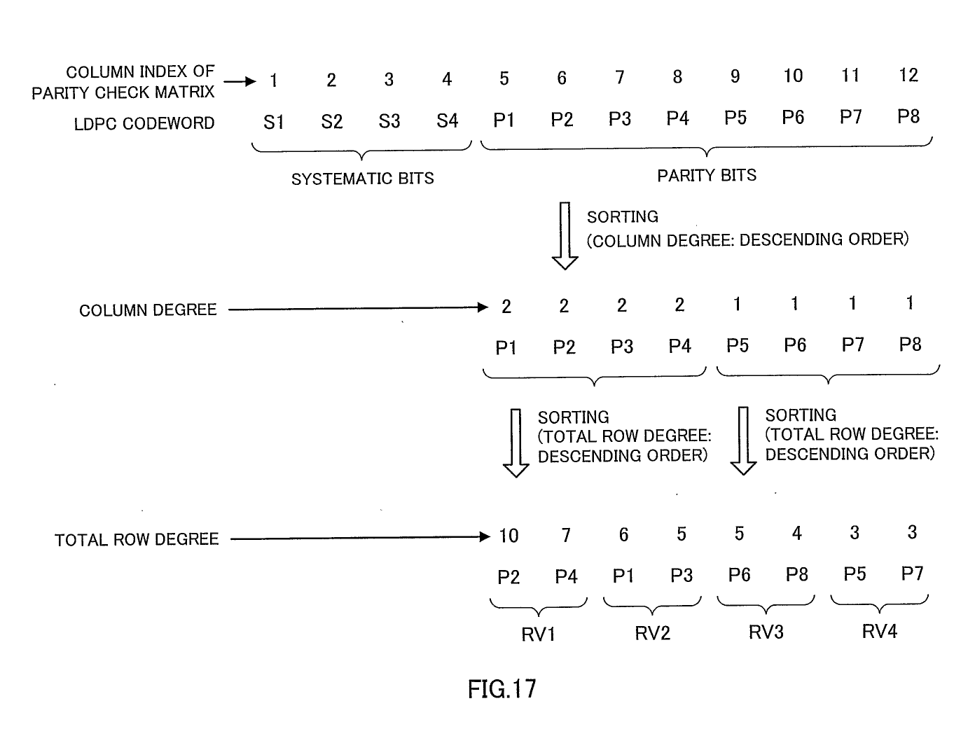

### FIG. 17

COLUMN INDEX OF PARITY CHECK MATRIX
LDPC CODEWORD
SYSTEMATIC BITS
PARITY BITS
   SORTING
   (COLUMN DEGREE: DESCENDING ORDER)
COLUMN DEGREE
   SORTING
   (TOTAL ROW DEGREE: DESCENDING ORDER)
   SORTING
   (TOTAL ROW DEGREE: DESCENDING ORDER)
TOTAL ROW DEGREE

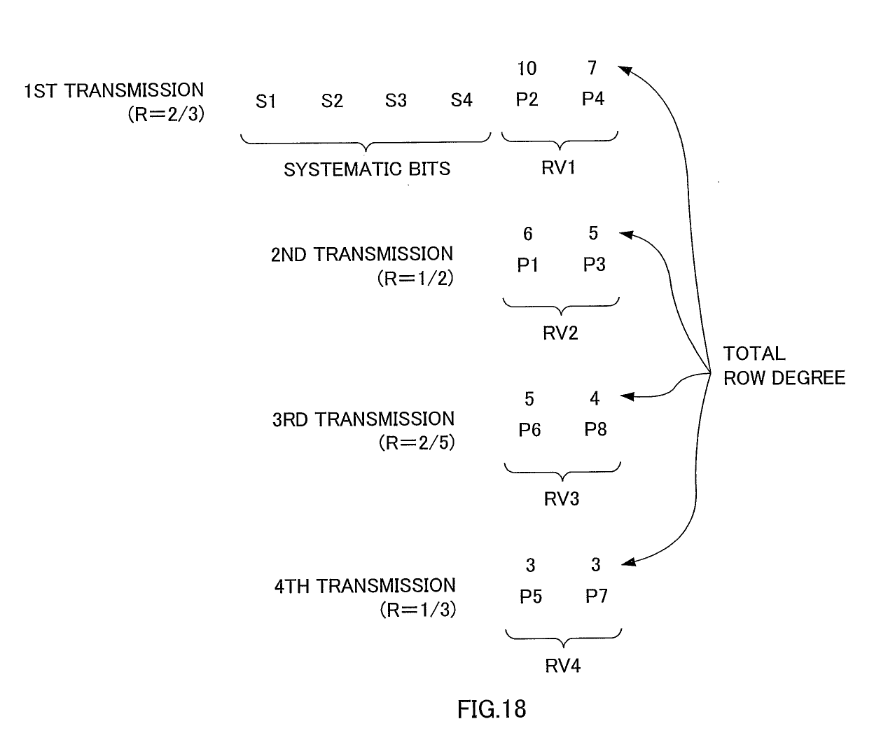

### FIG. 18

1ST TRANSMISSION
SYSTEMATIC BITS
2ND TRANSMISSION
3RD TRANSMISSION
4TH TRANSMISSION
TOTAL ROW DEGREE

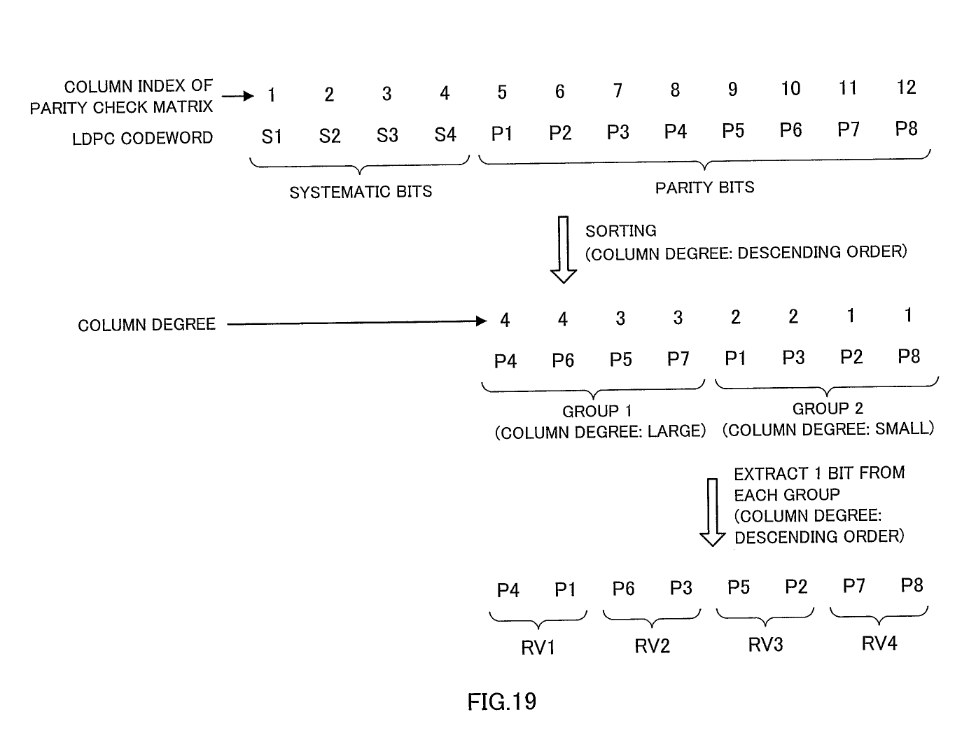

### FIG. 19

COLUMN INDEX OF PARITY CHECK MATRIX
LDPC CODEWORD
SYSTEMATIC BITS
PARITY BITS
   SORTING
   (COLUMN DEGREE: DESCENDING ORDER)
COLUMN DEGREE
   GROUP 1 (COLUMN DEGREE: LARGE)
      GROUP 2 (COLUMN DEGREE: SMALL)
   EXTRACT 1 BIT FROM EACH GROUP
   (COLUMN DEGREE: DESCENDING ORDER)

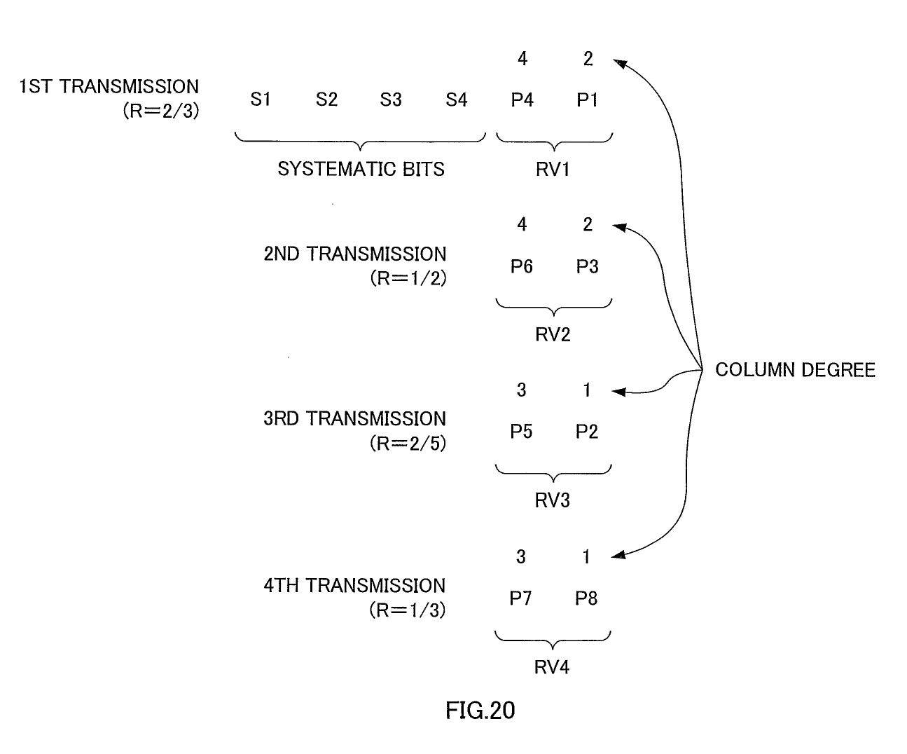

### FIG. 20

1ST TRANSMISSION
SYSTEMATIC BITS
2ND TRANSMISSION
3RD TRANSMISSION
4TH TRANSMISSION
COLUMN DEGREE

### BEST MODE FOR CARRYING OUT THE INVENTION

Embodiments of the present invention will now be described in detail with reference to the accompanying drawings.

### Embodiment 1

In this embodiment, the transmission order is controlled so that a plurality of RVs are transmitted in descending order of column degree in the parity check matrix until all parity bits contained in an LDPC codeword are transmitted.

The configuration of a transmitting-side radio communication apparatus 100 according to this embodiment is shown in FIG. 1.

In transmitting-side radio communication apparatus 100, a transmission bit sequence is input to an LDPC encoding section 101. LDPC encoding section 101 encodes the transmission bit sequence by LDPC encoding based on a parity check matrix to generate an LDPC codeword comprising systematic bits and parity bits. This LDPC codeword is output to an RV control section 102. LDPC encoding section 101 also outputs the parity check matrix to RV control section 102.

Based on the parity check matrix, RV control section 102 extracts each coded bit of the LDPC codeword and composes an RV, and outputs the RV to a modulation section 103. RV control section 102 also outputs an RV index for identifying an RV output to modulation section 103 to a multiplexing section 104. The number of RVs per transmission—that is, the number of RVs per RV control section 102 output—is given by (N·Rₘ(1−R))/(N_{RV}·R), where N is the LDPC codeword length, Rₘ is the mother coding rate, R is the 1st transmission (initial transmission) coding rate input from a control section 110, and N_{RV} is the number of bits per RV (that is, the number of bits composing one RV). RV control section 102 stores an LDPC codeword input from LDPC encoding section 101. Then, in the 1st transmission (initial transmission), RV control section 102 outputs all systematic bits contained in the LDPC codeword and an RV to modulation section 103. Also, if a NACK signal is input from control section 110—that is, in a 2nd or subsequent transmission (retransmission)—RV control section 102 outputs an RV to modulation section 103, and if an ACK signal is input from control section 110, RV control section 102 stops RV output to modulation section 103 and discards the stored LDPC codeword. Details of RV control processing by RV control section 102 will be given later herein.

In a 1st transmission (initial transmission), modulation section 103 modulates the systematic bits and RV input from RV control section 102 and generates data symbols, and outputs them to multiplexing section 104. In a 2nd or subsequent transmission (retransmission), modulation section 103 modulates an RV input from RV control section 102 and generates data symbols, and outputs them to characteristic parameter extraction section 104.

Multiplexing section 104 multiplexes a data symbol, pilot signal, and RV index, and a control signal input from control section 110, and outputs a generated multiplex signal to a radio transmitting section 105.

Radio transmitting section 105 performs transmission processing such as D/A conversion, amplification, and up-conversion on the multiplex signal, and transmits the resulting signal to the receiving-side radio communication apparatus from an antenna 106.

Meanwhile, a radio receiving section 107 receives a control signal transmitted from the receiving-side radio communication apparatus via antenna 106, performs reception processing such as down-conversion and A/D conversion on the control signal, and outputs the resulting signal to a demodulation section 108. A CQI (Channel Quality Indicator) and response signal (ACK signal or NACK signal) generated by the receiving-side radio communication apparatus are included in this control signal.

Demodulation section 108 demodulates the control signal and outputs the demodulated signal to a decoding section 109.

Decoding section 109 decodes the control signal and outputs the CQI and response signal contained in the control signal to control section 110.

Control section 110 controls the post-RV-control coding rate according to the CQI. Then control section 110 outputs a control signal indicating the determined coding rate to RV control section 102 and multiplexing section 104. The higher the channel quality to which the CQI corresponds, the higher is the post-RV-control coding rate determined by control section 110. Control section 110 also outputs the response signal input from decoding section 109 to RV control section 102.

RV control processing by RV control section 102 will now be described in detail.

FIG. 2 shows an 8-row×12-column parity check matrix as an example. As shown here, a parity check matrix is represented by a matrix of M rows×N columns, and comprises 0s and 1s.

Each column of a parity check matrix corresponds to a coded bit of an LDPC codeword. That is to say, when LDPC encoding is performed using the parity check matrix shown in FIG. 2, a 12-bit LDPC codeword is generated.

In the parity check matrix shown in FIG. 2, the column degree of the 1st column is the number of 1s in the 1st column—that is, 4—and the column degree of the 2nd column is the number of 1s in the 2nd column—that is, 4. Thus, in the 12-bit LDPC codeword, the column degree of the 1st bit is 4, and the column degree of the 2nd bit is 4. The same kind of rationale also applies to the 3rd through 12th columns.

Similarly, in the parity check matrix shown in FIG. 2, the row degree of the 1st row is the number of 1s in the 1st row—that is, 4—and the row degree of the 2nd row is the number of 1s in the 2nd row—that is, 6. The same kind of rationale also applies to the 3rd through 8th rows.

The parity check matrix shown in FIG. 2 can be represented by a′ Tanner graph comprising the rows and columns of the parity check matrix.

FIG. 3 shows a Tanner graph corresponding to the parity check matrix in FIG. 2. A Tanner graph comprises check nodes corresponding to the rows of a parity check matrix and variable nodes corresponding to the columns. That is to say, a Tanner graph corresponding to an 8-row×12-column parity check matrix is a two-part graph comprising eight check nodes and 12 variable nodes.

Each variable node of a Tanner graph corresponds to a coded bit of the LDPC codeword.

Variable nodes and check nodes of a Tanner graph are connected in accordance with the arrangement of 1s in the parity check matrix.

A concrete description will be now given based on variable nodes. The 1st variable node of the Tanner graph shown in FIG. 3 corresponds to the 1st column (N=1) of the parity check matrix shown in FIG. 2. The column degree of the 1st column of the parity check matrix is 4, and rows in which a 1 is located in the 1st column are the 2nd row, 3rd row, 6th row, and 8th row. Thus, there are four connections at the 1st variable node—2nd check node, 3rd check node, 6th check node, and 8th check node. Similarly, the 2nd variable node of the Tanner graph corresponds to the 2nd column (N=2) of the parity check matrix, the column degree of the 2nd column of the parity check matrix is 4, and rows in which a 1 is located in the 2nd column are the 1st row, 4th row, 5th row, and 7th row. Thus, there are four connections at the 2nd variable node—1st check node, 4th check node, 5th check node, and 7th check node. The same kind of rationale also applies to the 3rd variable node through the 12th variable node.

Similarly, to give a concrete description based on check nodes, the 1st check node of the Tanner graph shown in FIG. 3 corresponds to the 1st row (M=1) of the parity check matrix shown in FIG. 2. The row degree of the 1st row of the parity check matrix is 4, and columns in which a 1 is located in the 1st row are the 2nd column, 4th column, 8th column, and 11th column. Thus, there are four connections at the 1st check node—2nd variable node, 4th variable node, 8th variable node, and 11th variable node. Similarly, the 2nd check node of the Tanner graph corresponds to the 2nd row (M=2) of the parity check matrix, the row degree of the 2nd row of the parity check matrix is 6, and columns in which a 1 is located in the 2nd row are the 1st column, 3rd column, 4th column, 5th column, 9th column, and 10th column. Thus, there are six connections at the 2nd check node—1st variable node, 3rd variable node, 4th variable node, 5th variable node, 9th variable node, and 10th variable node. The same kind of rationale also applies to 3rd check node through 8th check node.

Thus, in a Tanner graph, variable nodes and check nodes are connected in accordance with the arrangement of 1s in a parity check matrix. That is to say, the number of check nodes connected to each variable node in a Tanner graph is equal to the column degree of each column in a parity check matrix. Also, check nodes to which each variable node is connected in a Tanner graph are check nodes corresponding to rows in which a 1 is located in each column of a parity check matrix. Similarly, the number of variable nodes connected to each check node in a Tanner graph is equal to the row degree of each row in a parity check matrix, and variable nodes to which each check node is connected in a Tanner graph are variable nodes corresponding to columns in which a 1 is located in each row of a parity check matrix.

The receiving-side radio communication apparatus decodes received data by performing mutual passing of likelihoods between variable nodes via check nodes, and iteratively performing updating of the likelihood of each variable node. Consequently, the larger the number of check node connections of a variable node (the larger the column degree of a variable node), the greater is the number of times likelihood passing is performed to other variable nodes.

RV control section 102 controls the RV transmission order so that a plurality of RVs are transmitted in order from an RV comprised of a parity bit corresponding to a variable node with a larger number of check node connections—that is, a variable node with a larger column degree—until all parity bits contained in an LDPC codeword are transmitted.

A description will be now given in concrete terms. In the following description it is assumed that the transmission bit sequence length is 4 bits, the mother coding rate Rₘ is ⅓, and the number of bits per RV, N_{RV}, is 2. Also, coding rate R determined by control section 110 is assumed to be ⅔. Therefore, when LDPC encoding is performed by LDPC encoding section 101 on a 4-bit transmission bit sequence using the parity check matrix shown in FIG. 2, an N=12-bit LDPC codeword comprising 4 systematic bits and 8 parity bits is generated. Also, since N_{RV}=2, RV control section 102 composes RVs with two parity bits each. Furthermore, RV control section 102 finds the number of RVs per output from (N·Rₘ(1−R))/(N_{RV}·R), and outputs one RV to modulation section 103 in one output.

RV control section 102 sorts parity bits corresponding to the 5th column through 12th column of the parity check matrix shown in FIG. 2 (5th variable node through 12th variable node of the Tanner graph shown in FIG. 3) in descending order of column degree in the parity check matrix (descending order of the number of check node connections), and extracts two parity bits at a time in order from a parity bit corresponding to a variable node of a larger column degree in the parity check matrix (a parity bit corresponding to a variable node with a larger number of check node connections) to compose one RV.

First, RV control section 102 compares column degrees among the 5th column through 12th column corresponding to parity bits of the parity check matrix shown in FIG. 2 (5th variable node through 12th variable node of the Tanner graph shown in FIG. 3). That is to say, RV control section 102 compares column degree 2 of the 5th column (the number of check node connections at 5th variable node is 2), column degree 1 of the 6th column (the number of check node connections at 6th variable node is 1), column degree 2 of the 7th column (the number of check node connections at 7th variable node is 2), column degree 4 of the 8th column (the number of check node connections at 8th variable node is 4), column degree 3 of the 9th column (the number of check node connections at 9th variable node is 3), column degree 4 of the 10th column (the number of check node connections at 10th variable node is 4), column degree 3 of the 11th column (the number of check node connections at 11th variable node is 3), and column degree 1 of the 12th column (the number of check node connections at 12th variable node is 1).

Thus, as shown in FIG. 2 and FIG. 3, RV configuration rankings in the 5th column through 12th column (5th variable node through 12th variable node) are as follows: the 8th column (8th variable node) and 10th column (10th variable node) first, the 9th column (9th variable node) and 11th column (11th variable node) second, the 5th column (5th variable node) and 7th column (7th variable node) third, and the 6th column (6th variable node) and 12th column (12th variable node) fourth. Then, since the number of bits composing one RV (N_{RV}) is 2, RV control section 102 follows the RV configuration rankings and, as shown in FIG. 4, sorts parity bits P1 through P8 in the 12-bit LDPC codeword comprising four systematic bits S1 through S4 and eight parity bits P1 through P8, and composes RV1 by extracting 8th column (8th variable node) parity bit P4 and 10th column (10th variable node) parity bit P6, composes RV2 by extracting 9th column (9th variable node) parity bit P5 and 11th column (11th variable node) parity bit P7, composes RV3 by extracting 5th column (5th variable node) parity bit P1 and 7th column (7th variable node) parity bit P3, and composes RV4 by extracting 6th column (6th variable node) parity bit P2 and 12th column (12th variable node) parity bit P8.

Thus, as shown in FIG. 5, RV control section 102 outputs a 6-bit LDPC codeword composed of four systematic bits S1 through S4 and RV1 comprising two parity bits P4 and P6 to modulation section 103 in the 1st transmission (initial transmission), outputs RV2 comprising two parity bits P5 and P7 to modulation section 103 in the 2nd transmission (1st retransmission), outputs RV3 comprising two parity bits P1 and P3 to modulation section 103 in the 3rd transmission (2nd retransmission), and outputs RV4 comprising two parity bits P2 and P8 to modulation section 103 in the 4th transmission (3rd retransmission). Also, RV control section 102 outputs “1” to multiplexing section 104 as the RV index in the 1st transmission (initial transmission), outputs “2” to multiplexing section 104 as the RV index in the 2nd transmission (1st retransmission), outputs “3” to multiplexing section 104 as the RV index in the 3rd transmission (2nd retransmission), and outputs “4” to multiplexing section 104 as the RV index in the 4th transmission (3rd retransmission). As shown in FIG. 5, coding rates R in these transmissions are ⅔ in the 1st transmission, ½ in the 2nd transmission, ⅖ in the 3rd transmission, and ⅓—the same as mother coding rate Rₘ—in the 4th transmission.

By composing RVs by extracting parity bits in descending order of column degree, RV control section 102 can control the order of transmission of RVs transmitted by radio communication apparatus 100 so that the RVs are transmitted in descending order of column degree.

Next, a receiving-side radio communication apparatus according to this embodiment will be described. The configuration of a receiving-side radio communication apparatus 200 according to this embodiment is shown in FIG. 6.

In receiving-side radio communication apparatus 200, a radio receiving section 202 receives a multiplex signal transmitted from transmitting-side radio communication apparatus 100 (FIG. 1) via an antenna 201, performs reception processing such as down-conversion and A/D conversion on the received signal, and outputs the resulting signal to a separation section 203. This received signal includes a data symbol, pilot signal, and RV index, and a control signal indicating a coding rate determined by transmitting-side radio communication apparatus 100.

Separation section 203 separates the received signal into a data symbol, pilot signal, RV index, and control signal. Then separation section 203 outputs the data symbol to a demodulation section 204, outputs the pilot signal to a channel quality estimation section 208, and outputs the RV index and control signal to an RV combining section 205.

Demodulation section 204 demodulates the data symbol and obtains received data, and outputs the received data to RV combining section 205.

When 1st transmission data (initial transmission data) is received, RV combining section 205 performs padding with padding bits having log-likelihood ratio 0 in the received data based on a parity check matrix (FIG. 2) identical to the parity check matrix used by LDPC encoding section 101 (FIG. 1), stores the obtained data, and also outputs the obtained data to an LDPC decoding section 206. On the other hand, when 2nd or subsequent transmission data (retransmission data) is received, RV combining section 205 combines the receive data with stored data based on the parity check matrix (FIG. 2), stores the obtained data, and also outputs the obtained data to an LDPC decoding section 206. If an ACK signal is input from an error detection section 207—that is, if there are no errors in the received data decoded in LDPC decoding section 206—RV combining section 205 discards the stored received data. The number of padding bits used for padding when receiving 1st transmission data is determined based on the difference between the LDPC encoding section 101 (FIG. 1) coding rate (mother coding rate) Rₘ and the coding rate indicated by the control signal input from separation section 203 (the coding rate determined by control section 110 (FIG. 1)) R. Specifically, the number of padding bits used for padding is given by Nᵣ((R/Rₘ)−1), where Nᵣ indicates the data length of the received data. Details of RV combining processing by RV combining section 205 will be given later herein.

Using a parity check matrix (FIG. 2) identical to the parity check matrix used by LDPC encoding section 101 (FIG. 1), LDPC decoding section 206 performs LDPC decoding on data input from RV combining section 205, and obtains a decoded bit sequence. This decoded bit sequence is output to error detection section 207.

Error detection section 207 performs error detection on the decoded bit sequence input from LDPC decoding section 206. If the result of error detection is that there is an error in the decoded bits, error detection section 207 generates a NACK signal as a response signal and outputs this NACK signal to RV combining section 205 and a control signal generation section 209, whereas if there is no error in the decoded bits, error detection section 207 generates an ACK signal as a response signal and outputs this ACK signal to RV combining section 205 and control signal generation section 209. If there is no error in the decoded bits, error detection section 207 outputs the decoded bit sequence as a received bit sequence.

Meanwhile, channel quality estimation section 208 estimates the channel quality using the pilot signal input from separation section 203. Here, channel quality estimation section 208 estimates the SINR (Signal to Interference and Noise Ratio) of the pilot signal as channel quality, and outputs the estimated SINR to control signal generation section 209.

Control signal generation section 209 generates a CQI corresponding to the SINR input from channel quality estimation section 208, and outputs a control signal containing the generated CQI and the response signal input from error detection section 207 to an encoding section 210.

Encoding section 210 encodes the control signal and outputs the resulting signal to a modulation section 211.

Modulation section 211 modulates the control signal and outputs the resulting signal to a radio transmitting section 212.

Radio transmitting section 212 performs transmission processing such as D/A conversion, amplification, and up-conversion on the control signal, and transmits the resulting signal to transmitting-side radio communication apparatus 100 (FIG. 1) from antenna 201.

RV combining processing by RV combining section 205 will now be described in detail. In the following description, a part corresponding to a systematic bit among columns of a parity check matrix or variable nodes of a Tanner graph is referred to as a systematic bit position, and a part corresponding to a parity bit is referred to as a parity bit position.

Here, since received data length Nᵣ is 6 bits, coding rate R indicated by a control signal input from separation section 203 is ⅔, and mother coding rate Rₘ is ⅓, RV combining section 205 finds the number of padding bits used for padding from Nᵣ((R/Rₘ)−1), and performs padding with six padding bits.

Prior to a 1st transmission (initial transmission), RV combining section 205—in the same way as RV control section 102 (FIG. 1)—sorts a plurality of parity bit positions in descending order of column degree in the parity check matrix (descending order of the number of check node connections), and extracts two parity bit positions at a time in order from a parity bit position corresponding to a variable node of a larger column degree (a parity bit position corresponding to a variable node with a larger number of check node connections) to compose one RV. Thus, in the same way as RV control section 102 (FIG. 1), RV combining section 205 composes RV1 with 8th column (8th variable node) parity bit position P4 and 10th column (10th variable node) parity bit position P6, composes RV2 with 9th column (9th variable node) parity bit position P5 and 11th column (11th variable node) parity bit position P7, composes RV3 with 5th column (5th variable node) parity bit position P1 and 7th column (7th variable node) parity bit position P3, and composes RV4 with 6th column (6th variable node) parity bit position P2 and 12th column (12th variable node) parity bit position P8.

Then, as shown in FIG. 7, when 1st transmission data (initial transmission data) is received, since the RV index input from separation section 203 is “1”, RV combining section 205 determines that the bits of the 6-bit receive data are systematic bits S1 through S4 of the 1st column through 4th column (1st variable node through 4th variable node), and 8th column (8th variable node) parity bit P4 and 10th column (10th variable node) parity bit P6 composing RV1. Then RV combining section 205 places systematic bits S1 through S4 in the corresponding systematic bit positions, and places parity bit P4 and parity bit P6 in the corresponding parity bit positions. That is to say, as shown in FIG. 7, RV combining section 205 places corresponding systematic bits S1 through S4 in the 1st column through 4th column (1st variable node through 4th variable node), places parity bit P4 in the 8th column (8th variable node), and places parity bit P6 in the 10th column (10th variable node). Then RV combining section 205 performs padding with padding bits P_{D} in positions equal to parity bit positions corresponding to columns other than columns corresponding to the identified bits—that is, the 5th column through 7th column (5th variable node through 7th variable node), the 9th column (9th variable node), the 11th column (11th variable node), and the 12th column (12th variable node). In other words, as shown in FIG. 7, RV combining section 205 performs padding with three padding bits P_{D} between S4 and P4 of the received data, performs padding with one padding bit P_{D} between P4 and P6, and performs padding with two padding bits P_{D} after P6. By this means, data with a data length of 12 bits—the same as that of an LDPC codeword generated by transmitting-side radio communication apparatus 100—can be obtained. When 1st transmission data (initial transmission data) is received, 12-bit data comprising S1, S2, S3, S4, P_{D}, P_{D}, P_{D}, P4, P_{D}, P6, P_{D}, P_{D} is input to LDPC decoding section 206.

Next, as shown in FIG. 7, when 2nd transmission data (1st retransmission data) is received, since the RV index input from separation section 203 is “2”, RV combining section 205 determines that the bits of the 2-bit receive data are 9th column (9th variable node) parity bit P5 and 11th column (11th variable node) parity bit P7 composing RV2. Therefore, in order to place parity bits P5 and P7 in their corresponding parity bit positions—that is, the 9th column (9th variable node) and 11th column (11th variable node)—RV combining section 205 combines P5 and 9th column (9th variable node) padding bit P_{D}, and combines P7 and 11th column (11th variable node) padding bit P_{D}. Thus, when 2nd transmission data (1st retransmission data) is received, 12-bit data comprising S1, S2, S3, S4, P_{D}, P_{D}, P_{D}, P4, P5, P6, P7, P_{D} is input to LDPC decoding section 206.

Also, as shown in FIG. 7, when 3rd transmission data (2nd retransmission data) is received, since the RV index input from separation section 203 is “3”, RV combining section 205 determines that the bits of the 2-bit receive data are 5th column (5th variable node) parity bit P1 and 7th column (7th variable node) parity bit P3 composing RV3. Therefore, in order to place parity bits P1 and P3 in their corresponding parity bit positions—that is, the 5th column (5th variable node) and 7th column (7th variable node)—RV combining section 205 combines P1 and 5th column (5th variable node) padding bit P_{D}, and combines P3 and 7th column (7th variable node) padding bit P_{D}. Thus, when 3rd transmission data (2nd retransmission data) is received, 12-bit data comprising S1, S2, S3, S4, P1, P_{D}, P3, P4, P5, P6, P7, P_{D} is input to LDPC decoding section 206.

Furthermore, as shown in FIG. 7, when 4th transmission data (3rd retransmission data) is received, since the RV index input from separation section 203 is “4”, RV combining section 205 determines that the bits of the 2-bit receive data are 6th column (6th variable node) parity bit P2 and 12th column (12th variable node) parity bit P8 composing RV4. Therefore, in order to place parity bits P2 and P8 in their corresponding parity bit positions—that is, the 6th column (6th variable node) and 12th column (12th variable node)—RV combining section 205 combines P2 and 6th column (6th variable node) padding bit P_{D}, and combines P8 and 12th column (12th variable node) padding bit P_{D}. Thus, when 4th transmission data (3rd retransmission data) is received, 12-bit data comprising S1, S2, S3, S4, P1, P2, P3, P4, P5, P6, P7, P8 is input to LDPC decoding section 206.

Thus, according to this embodiment, when an LDPC code is used in IR-type HARQ, the transmitting-side radio communication apparatus preferentially transmits parity bits having larger numbers of likelihood passes in LDPC decoding. Consequently, the receiving-side radio communication apparatus receives parity bits in order from a parity bit having a larger number of likelihood passes—that is, from a parity bit that contributes more to likelihood updating—among parity bits contained in an LDPC codeword, enabling LDPC decoding of receive data to be performed by passing of likelihoods to many bits from the time of 1st reception. Thus, optimal error rate performance can always be obtained, and the number of retransmissions can be minimized.

### Embodiment 2

In this embodiment, a case is described in which RVs are further transmitted after all parity bits contained in an LDPC codeword are transmitted.

The operation of an RV control section 102 according to this embodiment will now be described.

A variable node of fewer check node connections has fewer likelihood passes between variable nodes connected via check nodes. That is to say, a variable node of fewer check node connections receives fewer likelihoods and therefore yields smaller effect of likelihood updating. Thus, when RVs are further transmitted after all parity bits contained in an LDPC codeword are transmitted, it is preferable to perform likelihood supplementation by preferentially retransmitting an RV composed of a variable node of a smaller column degree. That is to say, a variable node of fewer check node connections yields greater effect of likelihood improvement by means of RV retransmission.

Thus, when RVs are further transmitted after all parity bits contained in an LDPC codeword are transmitted, RV control section 102 according to this embodiment controls the RV transmission order so that a plurality of RVs are transmitted in order from an RV composed of a variable node of fewer check node connections—that is, a variable node of a smaller column degree.

A description will be now given in concrete terms. First, in the same way as in Embodiment 1, RV control section 102 extracts parity bits whose column degrees of the parity check matrix shown in FIG. 2 have been sorted in descending order two at a time, and composes RV1 through RV4, as shown in FIG. 4. Then, in the same way as in Embodiment 1 (FIG. 5), RV1 through RV4 are transmitted in order until the 4th transmission (3rd retransmission), and all of parity bits P1 through P8 contained in an LDPC codeword are transmitted, as shown in FIG. 8.

Here, when RVs are further transmitted, RV control section 102 sorts parity bits corresponding to the 5th column through 12th column of the parity check matrix shown in FIG. 2 (5th variable node through 12th variable node of the Tanner graph shown in FIG. 3) in ascending order of column degree in the parity check matrix (ascending order of the number of check node connections), and extracts two parity bits at a time from a parity bit corresponding to a variable node of a smaller column degree (that is, from a parity bit corresponding to a variable node with fewer check node connections), to compose one RV. That is to say, RV control section 102 composes RVs so that the RVs are transmitted in the reverse order to that of RV transmission from the 1st transmission (initial transmission) through 4th transmission (3rd retransmission)—that is, in the order: RV4, RV3, RV2, RV1. Thus, as shown in FIG. 8, RV control section 102 outputs RV4 comprising parity bits P2 and P8 to modulation section 103 in the 5th transmission (4th retransmission), and outputs RV3 comprising parity bits P1 and P3 to modulation section 103 in the 6th transmission (5th retransmission). Also, RV control section 102 outputs “4” to multiplexing section 104 as the RV index in the 5th transmission (4th retransmission), and outputs “3” to multiplexing section 104 as the RV index in the 6th transmission (5th retransmission). As shown in FIG. 8, coding rate R in these transmissions is 2/7 in the 5th transmission and ¼ in the 6th transmission.

By composing RVs by extracting parity bits in ascending order of column degree of the parity bits in this way, RV control section 102 can control the order of transmission of RVs transmitted by radio communication apparatus 100 so that the RVs are transmitted from an RV composed of a parity bit of a smaller column degree.

RV combining section 205 of receiving-side radio communication apparatus 200 (FIG. 5) determines RV configuration by means of the same method as RV control section 102, and identifies bits subject to combining in accordance with the RV indexes reported from transmitting-side radio communication apparatus 100.

Thus, according to this embodiment, the likelihood of a parity bit, for which the column degree is small and the effect of likelihood improvement is small, can be supplemented by RV retransmission. By this means, the effect of likelihood updating for a systematic bit connected to that parity bit via a check node can be indirectly improved by an improvement in the likelihood of that parity bit. Therefore, according to this embodiment, if there is still an error in decoded bits after all parity bits have been transmitted, and further RV transmissions are necessary after all RVs have been transmitted, the error rate performance of parity bits for which there is a greater possibility of error can be improved preferentially, and the number of retransmissions can be minimized.

### Embodiment 3

This embodiment differs from Embodiment 2 in that RVs comprising only systematic bits are transmitted.

That is to say, when RVs are further transmitted after all parity bits contained in an LDPC codeword are transmitted, RV control section 102 according to this embodiment controls the RV transmission order so that a plurality of RVs are transmitted in order from an RV composed of a systematic bit corresponding to a variable node of fewer check node connections—that is, a variable node of a smaller column degree.

The operation of RV control section 102 according to this embodiment will now be described.

First, in the same way as in Embodiment 1, RV control section 102 extracts parity bits whose column degrees of the parity check matrix shown in FIG. 2 have been sorted in descending order two at a time, and composes RV1 through RV4, as shown in FIG. 9. Then, in the same way as in Embodiment 1 (FIG. 5), RV1 through RV4 are transmitted in order until the 4th transmission (3rd retransmission), and all of parity bits P1 through P8 contained in an LDPC codeword are transmitted, as shown in FIG. 10.

Here, when RVs are further transmitted, RV control section 102 sorts systematic bits corresponding to the 1st column through 4th column of the parity check matrix shown in FIG. 2 (1st variable node through 4th variable node of the Tanner graph shown in FIG. 3) in ascending order of column degree on parity check matrix (ascending order of the number of check node connections), and extracts two systematic bits at a time in order from a systematic bit corresponding to a variable node with a smaller column degree in parity check matrix (that is, a systematic bit corresponding to a variable node with fewer check node connections) to compose one RV.

First, RV control section 102 compares column degrees among the 1st column through 4th column corresponding to systematic bits of the parity check matrix shown in FIG. 2 (1st variable node through 4th variable node of the Tanner graph shown in FIG. 3). That is to say, RV control section 102 compares column degree 4 of the 1st column (the number of check node connections at 1st variable node is 4), column degree 4 of the 2nd column (the number of check node connections at 2nd variable node is 4), column degree 3 of the 3rd column (the number of check node connections at 3rd variable node is 3), and column degree 3 of the 4th column (the number of check node connections at 4th variable node is 3).

Thus, RV configuration rankings in the 1st column through 4th column (1st variable node through 4th variable node) are as follows: the 3rd column (3rd variable node) and 4th column (4th variable node) first, and the 1st column (1st variable node) and 2nd column (2nd variable node) second.

Then, since the number of bits composing one RV (N_{RV}) is 2, RV control section 102 follows the RV configuration rankings and, as shown in FIG. 9, sorts systematic bits S1 through S4, composes RV5 by extracting 3rd column (3rd variable node) systematic bit S3 and 4th column (4th variable node) systematic bit S4, and composes RV6 by extracting 1st column (1st variable node) systematic bit S1 and 2nd column (2nd variable node) systematic bit S2.

Thus, as shown in FIG. 10, RV control section 102 outputs RV5 comprising systematic bits S3 and S4 to modulation section 103 in the 5th transmission (4th retransmission), and outputs RV6 comprising systematic bits S1 and S2 to modulation section 103 in the 6th transmission (5th retransmission). Also, RV control section 102 outputs “5” to multiplexing section 104 as the RV index in the 5th transmission (4th retransmission), and outputs “6” to multiplexing section 104 as the RV index in the 6th transmission (5th retransmission). As shown in FIG. 10, coding rate R in these transmissions is 2/7 in the 5th transmission and ¼ in the 6th transmission.

By composing RVs by extracting systematic bits in ascending order of column degree of systematic bits in this way, RV control section 102 can control the order of transmission of RVs transmitted by radio communication apparatus 100 so that the RVs are transmitted from an RV composed of a systematic bit of a smaller column degree is transmitted.

RV combining section 205 of receiving-side radio communication apparatus 200 (FIG. 5) determines RV configuration by means of the same method as RV control section 102, and identifies bits subject to combining in accordance with the RV indexes reported from transmitting-side radio communication apparatus 100.

Thus, according to this embodiment, the likelihood of a systematic bit having a smaller column degree and for which the effect of likelihood improvement is small, can be supplemented by RV retransmission. By this means, the likelihoods of all systematic bits can be aligned at a high level. Therefore, according to this embodiment, if there is still an error in decoded bits after all parity bits have been transmitted, and further RV transmissions are necessary after all RVs have been transmitted, the error rate performance of systematic bits for which there is a greater possibility of error among systematic bits that are actual transmit bits can be improved preferentially, and the number of retransmissions can be minimized.

### Embodiment 4

This embodiment differs from Embodiment 2 in that RVs comprising systematic bits and parity bits are transmitted.

That is to say, when RVs are further transmitted after all parity bits contained in an LDPC codeword are transmitted, RV control section 102 according to this embodiment controls the RV transmission order so that a plurality of RVs are transmitted from an RV composed of a bit corresponding to a variable node of fewer check node connections—that is, a variable node of a smaller column degree.

The operation of RV control section 102 according to this embodiment will now be described. It is assumed here that the transmission bit sequence length is 4 bits, mother coding rate Rₘ is ⅓, and the number of bits per RV, N_{RV}, is 4. Also, coding rate R determined by control section 110 is assumed to be ½. Therefore, RV control section 102 finds the number of RVs per output from (N·Rₘ(1−R))/(N_{RV}·R), and outputs one RV to modulation section 103 in one output. Also, since N_{RV}=4, RV control section 102 composes RVs with four parity bits each, and obtains an 8-bit LDPC codeword comprising 4 bits as 1st transmission data (initial transmission data).

A description will be now given in concrete terms. First, as shown in FIG. 11, RV control section 102—in the same way as in Embodiment 1—sorts parity bits P1 through P8 of an LDPC codeword in descending order of column degree in the parity check matrix shown in FIG. 2, extracts four parity bits at a time in descending order of column degree, composes RV1 from P4, P6, P5, and P7, and composes RV2 from P1, P3, P2, and P8. Thus, as shown in FIG. 12, RV1 is transmitted in the 1st transmission (initial transmission) and RV2 is transmitted in the 2nd transmission (1st retransmission), and all of parity bits P1 through P8 contained in the LDPC codeword are transmitted by the end of the 2nd transmission.

Here, when RVs are further transmitted, RV control section 102 sorts the bits of an LDPC codeword corresponding to the 1st column through 12th column of the parity check matrix shown in FIG. 2 (1st variable node through 12th variable node of the Tanner graph shown in FIG. 3) in ascending order of column degree (ascending order of the number of check node connections), and extracts four bits at a time in ascending order of column degree of coded bits (bits corresponding to variable nodes with fewer check node connections) to compose one RV.

First, RV control section 102 compares column degrees among the 1st column through 12th column corresponding to bits of the parity check matrix shown in FIG. 2 (1st variable node through 12th variable node of the Tanner graph shown in FIG. 3).

Thus, RV configuration rankings in the 1st column through 12th column (1st variable node through 12th variable node) are as follows: the 6th column (6th variable node) and 12th column (12th variable node) first, the 5th column (5th variable node) and 7th column (7th variable node) second, the 3rd column (3rd variable node), 4th column (4th variable node), 9th column (9th variable node), and 11th column (11th variable node) third, and the 1st column (1st variable node), 2nd column (2nd variable node), 8th column (8th variable node), and 10th column (10th variable node) fourth.

Then, since the number of bits composing one RV (N_{RV}) is 4, RV control section 102 follows the RV configuration rankings and, as shown in FIG. 11, sorts systematic bits S1 through S4 and parity bits P1 through P8, composes RV3 by extracting 6th column (6th variable node) parity bit P2, 12th column (12th variable node) parity bit P8, 5th column (5th variable node) parity bit P1, and 7th column (7th variable node) parity bit P3, composes RV4 by extracting 3rd column (3rd variable node) systematic bit S3, 4th column (4th variable node) systematic bit S4, 9th column (9th variable node) parity bit P5, and 11th column (11th variable node) parity bit P7, and composes RV5 by extracting 1st column (1st variable node) systematic bit S1, 2nd column (2nd variable node) systematic bit S2, 8th column (8th variable node) parity bit P4, and 10th column (10th variable node) parity bit P6.

Thus, as shown in FIG. 12, RV control section 102 outputs RV3 comprising P2, P8, P1, and P3 to modulation section 103 in the 3rd transmission (2nd retransmission), outputs RV4 comprising S3, S4, P5, and P7 to modulation section 103 in the 4th transmission (3rd retransmission), and outputs RV5 comprising S1, S2, P4, and P6 to modulation section 103 in the 5th transmission (4th retransmission). Also, RV control section 102 outputs “3” to multiplexing section 104 as the RV index in the 3rd transmission (2nd retransmission), outputs “4” to multiplexing section 104 as the RV index in the 4th transmission (3rd retransmission), and outputs “5” to multiplexing section 104 as the RV index in the 5th transmission (4th retransmission). As shown in FIG. 12, coding rate R in these transmissions is ½ in the 1st transmission, ⅓—the same as mother coding rate Rₘ—in the 2nd transmission, ¼ in the 3rd transmission, ⅕ in the 4th transmission, and ⅙ in the 5th transmission.

By composing RVs by extracting bits in ascending order of column degree in this way, RV control section 102 can control the order of transmission of RVs transmitted by radio communication apparatus 100 so that the RVS are transmitted from an RV composed of a variable node of a smaller column degree is transmitted.

RV combining section 205 of receiving-side radio communication apparatus 200 (FIG. 5) determines RV configuration by means of the same method as RV control section 102, and identifies bits subject to combining in accordance with the RV indexes reported from transmitting-side radio communication apparatus 100.

Thus, according to this embodiment, the likelihoods of a systematic bit and parity bit for which the column degree is small and the effect of likelihood improvement is small, can be supplemented by RV retransmission. By this means, the likelihood of that systematic bit can be directly improved, and the effect of likelihood updating for a systematic bit connected to that parity bit via a check node can be indirectly improved by an improvement in the likelihood of that parity bit. Therefore, according to this embodiment, the effects of both Embodiment 2 and Embodiment 3 can be obtained simultaneously.

### Embodiment 5

This embodiment differs from Embodiment 1 in that a plurality of RVs are composed by dividing a plurality of parity bits of an LDPC codeword in the LDPC encoding section 101 output order.

That is to say, until all parity bits contained in an LDPC codeword are transmitted, RV control section 102 according to this embodiment composes a plurality of RVs by dividing a plurality of parity bits of an LDPC codeword in the LDPC encoding section 101 output order, and controls the RV transmission order so that a plurality of RVs are transmitted in order from an RV having a larger average value of column degrees of the parity bits belonging to the RV.

The operation of RV control section 102 according to this embodiment will now be described.

RV control section 102 divides parity bits P1 through P8 of an LDPC codeword two at a time in the order of output from LDPC encoding section 101, and composes one RV with two parity bits.

That is to say, as shown in FIG. 13, RV control section 102 first, taking an LDPC codeword comprising four systematic bits S1 through S4 and eight parity bits P1 through P8, makes 5th column (5th variable node) parity bit P1 and 6th column (6th variable node) parity bit P2 group 1, makes 7th column (7th variable node) parity bit P3 and 8th column (8th variable node) parity bit P4 group 2, makes 9th column (9th variable node) parity bit P5 and 10th column (10th variable node) parity bit P6 group 3, and makes 11th column (11th variable node) parity bit P7 and 12th column (12th variable node) parity bit P8 group 4.

Next, among groups 1 through 4, RV control section 102 compares the average values of the column degrees of the parity bits belonging to each group (the average numbers of check node connections of variable nodes corresponding to the parity bits belonging to each group). That is to say, RV control section 102 compares average value 1.5 of column degree 2 of the 5th column (check node connection quantity 2 of 5th variable node) and column degree 1 of the 6th column (check node connection quantity 1 of 6th variable node) of group 1, average value 3.0 of column degree 2 of the 7th column (check node connection quantity 2 of 7th variable node) and column degree 4 of the 8th column (check node connection quantity 4 of 8th variable node) of group 2, average value 3.5 of column degree 3 of the 9th column (check node connection quantity 3 of 9th variable node) and column degree 4 of the 10th column (check node connection quantity 4 of 10th variable node) of group 3, and average value 2.0 of column degree 3 of the 11th column (check node connection quantity 3 of 11th variable node) and column degree 1 of the 12th column (check node connection quantity 1 of 12th variable node) of group 4.

Then RV control section 102 sorts the average values of the column degrees (average column degrees) of groups 1 through 4, and composes RVs in descending order of the average values of column degrees (average column degrees). That is to say, as shown in FIG. 13, RV control section 102 composes RV1 with P5 and P6 of group 3, composes RV2 with P3 and P4 of group 2, composes RV3 with P7 and P8 of group 4, and composes RV4 with P1 and P2 of group 1.

Thus, as shown in FIG. 14, RV control section 102 outputs a 6-bit LDPC codeword composed of four systematic bits S1 through S4 and RV1 comprising two parity bits P5 and P6 to modulation section 103 in the 1st transmission (initial transmission), outputs RV2 comprising two parity bits P3 and P4 to modulation section 103 in the 2nd transmission (1st retransmission), outputs RV3 comprising two parity bits P7 and P8 to modulation section 103 in the 3rd transmission (2nd retransmission), and outputs RV4 comprising two parity bits P1 and P2 to modulation section 103 in the 4th transmission (3rd retransmission). Also, RV control section 102 outputs “1” to multiplexing section 104 as the RV index in the 1st transmission (initial transmission), outputs “2” to multiplexing section 104 as the RV index in the 2nd transmission (1st retransmission), outputs “3” to multiplexing section 104 as the RV index in the 3rd transmission (2nd retransmission), and outputs “4” to multiplexing section 104 as the RV index in the 4th transmission (3rd retransmission). Coding rate R in these transmissions is the same as in Embodiment 1.

By dividing a plurality of parity bits into a plurality of groups, and composing RVs by sorting the groups in descending order of the average value of the column degrees of the parity bits belonging to each RV in this way, RV control section 102 can control the order of transmission of RVs transmitted by radio communication apparatus 100 so that the RVS are transmitted in order from an RV having a larger average value of column degrees of parity bits belonging to the RV.

Thus, according to this embodiment, since RVs are composed by dividing LDPC codeword parity bits according to the LDPC encoding output order, RVs that take optimal error rate performance into consideration can easily be composed even when an LDPC codeword is extremely long.

### Embodiment 6

In this embodiment, a case will be described in which there are a plurality of RVs comprising parity bits with the same column degree in Embodiment 1.

The operation of RV control section 102 according to this embodiment will now be described.

The larger the number of variable node connections of a check node (the larger row degree of a check node), the larger the number of likelihood passes between variable nodes. Therefore, in the case of a variable node connected to a check node with a large number of variable node connections, the number of likelihoods passed via connected check nodes is proportionally larger, and the effect of likelihood updating is proportionally greater.

Thus, until all parity bits contained in an LDPC codeword are transmitted, RV control section 102 controls the RV transmission order so that, when there are a plurality of RVs comprising parity bits with the same column degree, a plurality of RVs are transmitted in order from an RV comprising parity bits corresponding to variable nodes connected to a check node with a larger number of variable node connections—that is, parity bits corresponding to variable nodes connected to a check node whose row degree is larger.

A description will be now given in concrete terms. In the following description, LDPC encoding is performed using the parity check matrix shown in FIG. 15. A Tanner graph corresponding to the parity check matrix shown in FIG. 15 is shown in FIG. 16.

In the same way as in Embodiment 1, RV control section 102 first sorts parity bits corresponding to the 5th column through 12th column of the parity check matrix shown in FIG. 15 (5th variable node through 12th variable node of the Tanner graph shown in FIG. 16) in descending order of column degree. The RV configuration rankings at this time are therefore as follows: the 5th column through 8th column (5th variable node through 8th variable node), all having a column degree of 2, first, and the 9th column through 12th column (9th variable node through 12th variable node), all having a column degree of 1, second.

However, while the number of bits composing one RV is 2, there are four columns—the 5th column through 8th column—with an RV configuration ranking of 1. Therefore, it is necessary to determine which of the 5th column through 8th column is to be given priority in composing each RV. Similarly, there are four columns—the 9th column through 12th column—with an RV configuration ranking of 2, and it is therefore necessary to determine which of the 9th column through 12th column is to be given priority in composing each RV.

Thus, RV control section 102 further sorts the parity bits corresponding to the 5th column through 8th column (5th variable node through 8th variable node) in descending connection-destination check node total row degree order (descending order of the number of connections with variable node at a connection-destination check node), and extracts two parity bits at a time in order from a parity bit corresponding to a variable node connected to a check node with a larger parity check matrix row degree (a parity bit corresponding to a variable node connected to a check node with the larger number of variable node connections) to compose one RV.

Specifically, among the 5th column through 8th column all having a column degree of 2, RV control section 102 further compares: the total row degree of the 5th column—that is, the total, 6, of row degree 3 of the 1st row in which a 1 is located in the 5th column (the number of variable node connections in 1st check node which connects 5th variable node is 3) and row degree 3 of the 5th row in which a 1 is located in the 5th column (the number of variable node connections in 5th check node which connects 5th variable node is 3); the total row degree of the 6th column—that is, the total, 10, of row degree 5 of the 2nd row in which a 1 is located in the 6th column (the number of variable node connections in 2nd check node which connects 6th variable node is 5) and row degree 5 of the 6th row in which a 1 is located in the 6th column (the number of variable node connections in 6th check node which connects 6th variable node is 5); the total row degree of the 7th column—that is, the total, 5, of row degree 3 of the 3rd row in which a 1 is located in the 7th column (the number of variable node connections in 3rd check node which connects 7th variable node is 3) and row degree 2 of the 7th row in which a 1 is located in the 7th column (the number of variable node connections in 7th check node which connects 7th variable node is 2); and the total row degree of the 8th column—that is, the total, 7, of row degree 3 of the 4th row in which a 1 is located in the 8th column (the number of variable node connections in 4th check node which connects 8th variable node is 3) and row degree 4 of the 8th row in which a 1 is located in the 8th column (the number of variable node connections in 8th check node which connects 8th variable node is 4). That is to say, among variable node 5 through variable node 8 of the Tanner graph shown in FIG. 16, RV control section 102 compares the totals of the numbers of connections to variable nodes at check nodes connected to each variable node.

Thus, as shown in FIG. 15 and FIG. 16, RV configuration rankings in the 5th column through 8th column are as follows: the 6th column (6th variable node) and 8th column (8th variable node) first, and the 5th column (5th variable node) and 7th column (7th variable node) second.

RV control section 102 also carries out the same kind of processing for the 9th column through 12th column, all having a column degree of 1, sorting the parity bits corresponding to the 9th column through 12th column (9th variable node through 12th variable node) in descending connection-destination check node total row degree order (descending order of the number of connections with variable node at a connection-destination check node). Thus, as shown in FIG. 15 and FIG. 16, RV configuration rankings in the 9th column through 12th column of the 5th column through 12th column are as follows: the 10th column (10th variable node) and 12th column (12th variable node) third, and the 9th column (9th variable node) and 11th column (11th variable node) fourth.

Then, since the number of bits composing one RV (N_{RV}) is 2, RV control section 102 follows the RV configuration rankings and, as shown in FIG. 17, further sorts parity bits P1 through P8, and composes RV1 by extracting 6th column (6th variable node) parity bit P2 and 8th column (8th variable node) parity bit P4, composes RV2 by extracting 5th column (5th variable node) parity bit P1 and 7th column (7th variable node) parity bit P3, composes RV3 by extracting 10th column (10th variable node) parity bit P6 and 12th column (12th variable node) parity bit P8, and composes RV4 by extracting 9th column (9th variable node) parity bit P5 and 11th column (11th variable node) parity bit P7.

Thus, as shown in FIG. 18, RV control section 102 outputs an LDPC codeword composed of four systematic bits S1 through S4 and RV1 comprising two parity bits P2 and P4 to modulation section 103 in the 1st transmission (initial transmission), outputs RV2 comprising two parity bits P1 and P3 to modulation section 103 in the 2nd transmission (1st retransmission), outputs RV3 comprising two parity bits P6 and P8 to modulation section 103 in the 3rd transmission (2nd retransmission), and outputs RV4 comprising two parity bits P5 and P7 to modulation section 103 in the 4th transmission (3rd retransmission). Also, RV control section 102 outputs “1” to multiplexing section 104 as the RV index in the 1st transmission (initial transmission), outputs “2” to multiplexing section 104 as the RV index in the 2nd transmission (1st retransmission), outputs “3” to multiplexing section 104 as the RV index in the 3rd transmission (2nd retransmission), and outputs “4” to multiplexing section 104 as the RV index in the 4th transmission (3rd retransmission). Coding rate R in these transmissions is the same as in Embodiment 1.

By composing RVs by extracting parity bits in order from those with a larger connection-destination check node total row degree in this way, RV control section 102 can control the order of transmission of RVs transmitted by radio communication apparatus 100, so that transmission is performed in order from an RV comprising parity bits corresponding to a variable node connected to a check node with a larger row degree.

Thus, according to this embodiment, optimal error rate performance can always be obtained, and the number of retransmissions can be minimized, even when there are a plurality of RVs having the same column degree.

### Embodiment 7

This embodiment differs from Embodiment 1 in that a plurality of parity bits of an LDPC codeword are divided into a first group comprising parity bits with a large column degree and a second group comprising parity bits with a small column degree, and RVs are composed in order from a parity bit with a larger column degree in the first group and a parity bit with a larger column degree in the second group.

That is to say, until all parity bits contained in an LDPC codeword are transmitted, RV control section 102 according to this embodiment divides a plurality of parity bits of an LDPC codeword into a group 1 comprising parity bits with a large column degree and a group 2 comprising parity bits with a small column degree, and controls the RV transmission order so that RVs are transmitted in order from an RV comprising a parity bit with a larger column degree in group 1 and a parity bit with the larger column degree in group 2.

The operation of RV control section 102 according to this embodiment will now be described.

First, as shown in FIG. 19, RV control section 102 sorts parity bits P1 through P8 of an LDPC codeword in descending column degree order of the parity check matrix shown in FIG. 2.

Then RV control section 102 divides parity bits P1 through P8 into group 1 with large column degrees and group 2 with small column degrees. Specifically, as shown in FIG. 19, RV control section 102 classifies parity bit P4 of the 8th column with a column degree of 4 (8th variable node with four check node connections), parity bit P6 of the 10th column with a column degree of 4 (10th variable node with four check node connections), parity bit P5 of the 9th column with a column degree of 3 (9th variable node with three check node connections), and parity bit P7 of the 11th column with a column degree of 3 (11th variable node with three check node connections) into group 1 with large column degrees, and classifies parity bit P1 of the 5th column with a column degree of 2 (5th variable node with two check node connections), parity bit P3 of the 7th column with a column degree of 2 (7th variable node with two check node connections), parity bit P2 of the 6th column with a column degree of 1 (6th variable node with one check node connection), and parity bit P8 of the 12th column with a column degree of 1 (12th variable node with one check node connection) into group 2 with small column degrees.

Then RV control section 102 composes RVs by extracting parity bits in order from a parity bit with a larger column degree in each group. That is to say, since the number of bits composing one RV (N_{RV}) is 2, as shown in FIG. 19 RV control section 102 composes RV1 with P4 extracted from group 1 and P1 extracted from group 2, composes RV2 with P6 extracted from group 1 and P3 extracted from group 2, composes RV3 with P5 extracted from group 1 and P2 extracted from group 2, and composes RV4 with P7 extracted from group 1 and P8 extracted from group 2.

Thus, as shown in FIG. 20, RV control section 102 outputs an LDPC codeword composed of four systematic bits S1 through S4 and RV1 comprising two parity bits P4 and P1 to modulation section 103 in the 1st transmission (initial transmission), outputs RV2 comprising two parity bits P6 and P3 to modulation section 103 in the 2nd transmission (1st retransmission), outputs RV3 comprising two parity bits P5 and P2 to modulation section 103 in the 3rd transmission (2nd retransmission), and outputs RV4 comprising two parity bits P7 and P8 to modulation section 103 in the 4th transmission (3rd retransmission). Also, RV control section 102 outputs “1” to multiplexing section 104 as the RV index in the 1st transmission (initial transmission), outputs “2” to multiplexing section 104 as the RV index in the 2nd transmission (1st retransmission), outputs “3” to multiplexing section 104 as the RV index in the 3rd transmission (2nd retransmission), and outputs “4” to multiplexing section 104 as the RV index in the 4th transmission (3rd retransmission). Coding rate R in these transmissions is the same as in Embodiment 1.

By classifying a plurality of parity bits into a group with large column degrees and a group with small column degrees, and composing RVs by extracting parity bits in order from those with a larger column degree in each group in this way, RV control section 102 can control the order of transmission of RVs transmitted by radio communication apparatus 100 so that transmission is performed in order from an RV comprising a parity bit with a larger column degree in group 1 and a parity bit with a larger column degree in group 2.

Thus, according to this embodiment, two effects can be obtained synergistically: a likelihood updating contributive effect by parity bits with a large column degree and a large number of likelihood passes, and an effect of improving error rate performance by direct likelihood supplementation by means of RV retransmission for parity bits for which there is a high probability of error because the column degree is small and the effect of likelihood improvement is small.

This concludes the description of embodiments of the present invention.

In the above embodiments, a case in which the present invention is implemented in an FDD (Frequency Division Duplex) system has been taken as an example, but it is also possible for the present invention to be implemented in a TDD (Time Division Duplex) system. In the case of a TDD system, correlativity between uplink propagation path characteristics and downlink propagation path characteristics is extremely high, and therefore transmitting-side radio communication apparatus 100 can estimate reception quality in receiving-side radio communication apparatus 200 using a signal from receiving-side radio communication apparatus 200. Therefore, in the case of a TDD system, channel quality may be estimated by transmitting-side radio communication apparatus 100 without having receiving-side radio communication apparatus 200 issue a channel quality notification by means of a CQI.

The parity check matrixes shown in FIG. 2 and FIG. 15 are only examples, and parity check matrixes that can be used in implementing the present invention are not limited to those shown in FIG. 2 and FIG. 15.

In the above embodiments, transmitting-side radio communication apparatus 100 reports an RV index to receiving-side radiocommunication apparatus 200 every data transmission, but if a correspondence between the number of transmissions and RV indexes is established beforehand, and that correspondence is known by both transmitting-side radio communication apparatus 100 and receiving-side radio communication apparatus 200, receiving-side radio communication apparatus 200 can identify an RV index from the number of transmissions, and transmitting-side radio communication apparatus 100 need not report RV indexes.

In the above embodiments, RV control section 102 sorts bits of an LDPC codeword according to column degree, and composes an RV by extracting sorted bits, but RV control section 102 may omit the step of sorting bits of an LDPC codeword, and compose an RV by extracting bits directly according to column degree.

In the above embodiments, RV combining section 205 combines a padding bit and a received bit, but RV combining section 205 may combine an immediately preceding post-decoding likelihood and a received bit.

Also, error detection section 207 may perform error detection by means of a CRC (Cyclic Redundancy Check).

Furthermore, a coding rate set by control section 110 of transmitting-side radio communication apparatus 100 is not limited to one set according to channel quality, and a fixed coding rate may be used instead.

In the above embodiments, SINR is estimated as channel quality, but SNR, SIR, CINR, received power, interference power, bit error rate, throughput, an MCS (Modulation and Coding Scheme) that enables a predetermined error rate to be achieved, or the like, may be estimated as channel quality instead. Furthermore, CQI may also be expressed as CSI (Channel State Information).

In a mobile communication system, transmitting-side radio communication apparatus 100 can be provided in a radio communication base station apparatus, and receiving-side radio communication apparatus 200 can be provided in a radio communication mobile station apparatus. Also, transmitting-side radio communication apparatus 100 can be provided in a radio communication mobile station apparatus, and receiving-side radio communication apparatus 200 can be provided in a radio communication base station apparatus. By this means, a radio communication base station apparatus and radio communication mobile station apparatus can be implemented that offer the same kind of operation and effects as described above.

Also, a radio communication mobile station apparatus may be referred to as “UE”, and a radio communication base station apparatus as “Node B”.

In the above embodiments, a case has been described by way of example in which the present invention is configured as hardware, but it is also possible for the present invention to be implemented by software.

The function blocks used in the descriptions of the above embodiments are typically implemented as LSIs, which are integrated circuits. These may be implemented individually as single chips, or a single chip may incorporate some or all of them. Here, the term LSI has been used, but the terms IC, system LSI, super LSI, and ultra LSI may also be used according to differences in the degree of integration.

The method of implementing integrated circuitry is not limited to LSI, and implementation by means of dedicated circuitry or a general-purpose processor may also be used. An FPGA (Field Programmable Gate Array) for which programming is possible after LSI fabrication, or a reconfigurable processor allowing reconfiguration of circuit cell connections and settings within an LSI, may also be used.

In the event of the introduction of an integrated circuit implementation technology whereby LSI is replaced by a different technology as an advance in, or derivation from, semiconductor technology, integration of the function blocks may of course be performed using that technology. The adaptation of biotechnology or the like is also a possibility.

### INDUSTRIAL APPLICABILITY

The present invention can be applied to a mobile communication system or the like.

1. A transmitting-side radio communication apparatus that extracts each bit of a codeword comprising a systematic bit and a parity bit obtained by LDPC encoding based on a parity check matrix to compose a plurality of redundancy versions, and transmits the plurality of redundancy versions sequentially, the radio communication apparatus comprising:
an encoding section that encodes a transmission bit sequence by the LDPC encoding based on the parity check matrix to generate the codeword; and
a control section that controls a transmission order of the plurality of redundancy versions according to a column degree of each bit belonging to the plurality of redundancy versions, in the parity check matrix.

2. The radio communication apparatus according to claim 1, wherein the control section, until all parity bits contained in the codeword are transmitted, controls the transmission order so that the plurality of redundancy versions are transmitted in descending order of the column degree.

3. The radio communication apparatus according to claim 1, wherein the control section, until all parity bits contained in the codeword are transmitted, divides a plurality of parity bits of the codeword in an output order of the encoding section to compose the plurality of redundancy versions, and controls the transmission order so that the plurality of redundancy versions are transmitted in descending order of an average column degree of each redundancy version.

4. The radio communication apparatus according to claim 1, wherein the control section, until all parity bits contained in the codeword are transmitted, controls the transmission order so that the plurality of redundancy versions are transmitted in descending order of the column degree, and, when there are a plurality of redundancy versions having a same column degree, in descending order of a related row degree.

5. The radio communication apparatus according to claim 1, wherein the control section, until all parity bits contained in the codeword are transmitted, divides a plurality of parity bits of the codeword into a first group comprising a parity bit of a larger column degree and a second group comprising a parity bit of a smaller column degree, and controls the transmission order so that the plurality of redundancy versions are transmitted in order from a redundancy version comprising a parity bit of a largest column degree in the first group and a parity bit of a largest column degree in the second group.

6. The radio communication apparatus according to claim 1, wherein the control section, when a redundancy version is further transmitted after all parity bits contained in the codeword are transmitted, controls the transmission order so that the plurality of redundancy versions are transmitted in ascending order of the column degree.

7. The radio communication apparatus according to claim 6, wherein the control section, when a redundancy version is further transmitted after all parity bits contained in the codeword are transmitted, composes a redundancy version comprising a systematic bit only.

8. The radio communication apparatus according to claim 6, wherein the control section, when a redundancy version is further transmitted after all parity bits contained in the codeword are transmitted, composes a redundancy version comprising a parity bit only.

9. A receiving-side radio communication apparatus comprising:
a receiving section that receives one of a plurality of redundancy versions composed by extracting each bit of a codeword comprising a systematic bit and a parity bit obtained by LDPC encoding based on a parity check matrix;
an identifying section that identifies each received bit of a received redundancy version in accordance with a column degree in the parity check matrix, and arranges each identified received bit to a corresponding bit position to generate received data; and
a decoding section that decodes the received data by LDPC decoding based on the parity check matrix.

10. A radio communication base station apparatus comprising the radio communication apparatus according to claim 1.

11. A radio communication mobile station apparatus comprising the radio communication apparatus according to claim 1.

12. A transmission control method for a plurality of redundancy versions comprising each bit of a codeword comprising a systematic bit and a parity bit obtained by LDPC encoding based on a parity check matrix, wherein a transmission order of the plurality of redundancy versions is controlled according to a column degree of each bit belonging to the plurality of redundancy versions, in the parity check matrix.

13. A radio communication base station apparatus comprising the radio communication apparatus according to claim 9.

14. A radio communication mobile station apparatus comprising the radio communication apparatus according to claim 9.
